(19) United States
(12) Patent Application Publication
(10) Pub. No.: US 2012/0255853 A1
(43) Pub. Date: Oct. 11, 2012

(54) Method for Producing Superoxide, Method for Evaluating Superoxide Scavenging Ability, Device for Producing Superoxide, and Device for Evaluating Superoxide Scavenging Ability

(75) Inventors: Fujii Hirotada, Hokkaido (JP); Shunji Kohri, Hokkaido (JP)

(73) Assignee: Sapporo Medical University, Hokkaido (JP)

(21) Appl. No.: 13/514,876

(22) PCT Filed: Dec. 8, 2010
(86) PCT No.: PCT/JP2010/072050

§ 371 Date: Jun. 8, 2012

(30) Foreign Application Priority Data
Dec. 9, 2009 (JP) 2009-279015

(51) Int. Cl. B01J 19/12; G01R 33/28; B01J 19/08

(52) U.S. Cl. 204/157.6; 422/119; 324/317

(57) ABSTRACT

A method for easily and stably producing a superoxide by selectively generating the superoxide or a radical containing the superoxide at a high purity; a method for easily evaluating the superoxide scavenging ability of a subject sample; a device for easily and stably producing a superoxide by selectively generating the superoxide or a radical containing the superoxide at a high purity; and a device for easily evaluating the superoxide scavenging ability of a subject sample are provided. The method for producing a superoxide includes: a step (a) for preparing a solution for determination; a step (b) for forming a spin adduct/radical for determination; a step (c) for acquiring a spectrum for determination; a step (d) for determining similarity; a step (e) for acquiring flavin concentration; a step (f) for preparing a starting material solution; and a step (g) for generation.

### CROSS REFERENCE TO RELATED APPLICATIONS

This application is the national phase filing of international patent application No. PCT/JP2010/072050, filed 8 Dec. 2010, and claims priority of Japanese patent application number 2009-279015, filed 9 Dec. 2009, the entireties of which applications are incorporated herein by reference.

### FIELD OF THE INVENTION

The present invention relates to a method for producing superoxide, a method for evaluating the superoxide scavenging ability, a device for producing superoxide, and a device for evaluating the superoxide scavenging ability.

### BACKGROUND OF THE INVENTION

Superoxide (superoxide, a superoxide anion, and a superoxide anion radical) is a substance made up of an oxygen molecule that has gained an electron, and is expressed by the chemical formula (.O₂—). That is, superoxide is a kind of radicals (free radicals) having unpaired electrons. The unpaired electron refers to an electron that is not in a pair, which is located in the outermost orbit of a molecule or an atom. Generally, radicals are highly reactive substances, which oxidize or reduce other substances to get rid of such unpaired electrons.

Also, superoxide is a kind of reactive oxygen species. The reactive oxygen species refer to oxygen derivatives, which are generally extremely unstable and exhibit strong oxidizability through chemical activation of oxygen. Superoxide is the most abundantly generated reactive oxygen species in the living body, and is constitutively generated by enzymes such as xanthine oxidase, NAD(P)H oxidase, and aldehyde oxidase in the energy metabolism system, nucleic acid metabolism system, immune system, etc. Also, the generation of superoxide is accelerated by exposure to stimuli such as smoking, anti-cancer drugs, ultraviolet rays, herbicide, stress, and exhaust gas. The generated superoxide is known to exert a germicidal action on invading pathogenic microorganisms in the immune system, playing an important role in the living body defense.

Meanwhile, superoxide produced in excess in the living body is converted into reactive oxygen species having stronger oxidizability than superoxide such as hydrogen peroxide and hydroxy radicals (.OH—) by a spontaneous disproportionation reaction. As a result, superoxide causes oxidative degeneration of various substances such as nucleic acid, enzymes, and cell membrane, leading to an assumption that superoxide is one starting material of oxidative damage in the living body, causing disease and aging. In view of the foregoing, nowadays, research on the effect of superoxide on the living body is ongoing and a search for a substance that inhibits the superoxide activity is being carried out, etc., with rising demand for a technology of generating superoxide without generating unnecessary radicals.

Conventionally, as a method for generating superoxide, for example, a method for generating superoxide by allowing xanthine oxidase to act on hypoxanthine (Non Patent Literature 1), a method of dissolving potassium superoxide (KO₂) in water (Non Patent Literature 2), a method for generating superoxide by applying an electrical current between an anode and a cathode with a redox polymer (Patent Literature 1), a method for generating superoxide by irradiating a water-immersed aluminum anodic oxide coating with ultraviolet rays (Patent Literature 2), a method for generating superoxide by applying a high voltage to a sealed electric discharge tube containing mixed gases (Patent Literature 3), a method employing the pulse radiolysis method (Non Patent Literature 3), and a method of irradiating flavin and electron donors with light (Non Patent Literatures 4 to 7) are known.

### CITATION LIST

### Patent Literature

Patent Literature 1: Japanese Patent Laid-Open No. 2002-273433
Patent Literature 2: Japanese Patent Laid-Open No. 2003-112053
Patent Literature 3: Japanese Patent Laid-Open No. 10-152306

### Non Patent Literature

Non Patent Literature 1: Finkelstein E. et al., J. Mol. Pharmacol., Vol. 16, pages 676 to 685, 1979
Non Patent Literature 2: Harbour J R. et al., J. Phys. Chem., Vol. 82, pages 1379 to 1399, 1978
Non Patent Literature 3: Redpath J L. et al., Int. J. Radiat. Biol. Relat. Stud. Phys. Chem. Med. Vol. 33, pages 309 to 315, 1978
Non Patent Literature 4: Massey V. et al., Annu. Rev. Biochem., Vol. 32, pages 579 to 638, 1963
Non Patent Literature 5: Massey V. et al., FEES Lett., Vol. 84, No. 1, pages 5 to 21, 1977
Non Patent Literature 6: C. Beaucham et al., Analy. Biochem., Vol. 44, pages 276 to 287, 1971
Non Patent Literature 7: H. P. Misira et al., ABB, Vol. 181, pages 308 to 312, 1977

However, the method disclosed in Non Patent Literature 1 cannot guarantee stable generation of superoxide since it causes reduction and loss of enzyme activity. Also, it is difficult to control the amount of superoxide generated by the method disclosed in Non Patent Literature 2. Further, the method disclosed in Non Patent Literature 3 generates not only superoxide, but also other molecules such as hydroxy radicals and hydrated electrons, thereby failing to selectively generate superoxide. In this regard, the methods disclosed in Patent Literatures 1 and 2 also generate not only superoxide, but also other molecules such as hydroxy radicals, hydrogen peroxide, or ozone, thereby failing to selectively generate superoxide in a similar way. The methods disclosed in Non Patent Literatures 4 to 7 also generate not only superoxide, but also other molecules such as radicals derived from the electron donor (electron donor radicals, interfering radicals, and TH. radicals), thereby failing to selectively generate superoxide. Further, the method disclosed in Non Patent Literature 3 cannot be considered as a simple method since it requires a radiation irradiating device. In this regard, the method disclosed in Patent Literature 3 cannot be considered as a simple method either since it requires not only a high voltage, but also to keep the inside of an electric discharge tube under negative pressure.

### SUMMARY OF THE INVENTION

The present invention was completed in order to solve the aforementioned problems. The present invention aims to provide a method for simply and stably producing superoxide by selectively generating superoxide or a radical containing superoxide at a high purity, a method for simply evaluating the superoxide scavenging ability of the sample of interest, a device for simply and stably producing superoxide or a radical containing superoxide at a high purity by selectively generating superoxide or a radical containing superoxide at a high purity, and a device for simply evaluating the superoxide scavenging ability of the sample of interest.

The present inventors conducted intensive research. As a result, they have found that superoxide or a radical containing superoxide at a high purity can be simply and stably produced by selectively generating superoxide or a radical containing superoxide at a high purity while suppressing the amount of the electron donor radical generated by irradiating a solution for determination containing flavin, an electron donor, a spin trap agent, and an aqueous solvent with light to generate a superoxide spin adduct, a spin adduct of an electron donor radical (interfering radical or TH. radical), and/or an electron donor radical (interfering radical or TH. radical); acquiring a spectrum by electron spin resonance; acquiring the concentration of flavin based on the determination of whether or not the spectrum thus obtained is similar to the standard spectrum of a superoxide spin adduct (standard spectrum of superoxide); and then irradiating, with light, a starting material solution containing flavin at the concentration as acquired above, an electron donor, and an aqueous solvent. They have also found that by preparing a solution for evaluation containing flavin at the concentration as acquired in a similar way, an electron donor, a spin trap agent, a sample to be evaluated for its superoxide scavenging ability, and an aqueous solvent; irradiating the resulting solution with light; acquiring a spectrum by electron spin resonance; and then comparing the spectrum thus obtained with the standard spectrum of a superoxide spin adduct, the superoxide scavenging ability of the above sample can be evaluated. Based on the foregoing findings, the present inventors completed each of the following inventions.

(1) A method for producing superoxide, comprising the following steps of (a), (b), (c), (d), (e), (f), and (g);

(a) a step for preparing a solution for determination, comprising preparing a solution for determination containing flavin, an electron donor, a spin trap agent, and an aqueous solvent,
(b) a step for generating a spin adduct/radical for determination, comprising generating a superoxide spin adduct, an electron donor radical spin adduct, and/or an electron donor radical by irradiating the solution for determination with light,
(c) a step for acquiring a spectrum for determination, comprising acquiring a spectrum by detecting the superoxide spin adduct, the electron donor radical spin adduct, and/or the electron donor radical thus generated by electron spin resonance,
(d) a step for determining similarity, comprising determining whether or not a standard spectrum of a superoxide spin adduct and the spectrum for determination are similar,
(e) a step for acquiring a flavin concentration, comprising acquiring a concentration of flavin that is found similar by the similarity determination,
(f) a step for preparing a starting material solution, comprising preparing a starting material solution containing flavin at the concentration as acquired above, an electron donor, and an aqueous solvent, and
(g) a step for generation, comprising generating superoxide by irradiating the starting material solution with light.

(2) The method for producing superoxide according to (1), wherein the method comprises the following step (h) instead of the steps (a), (b), (c), (d), (e), and (f), when flavin is riboflavin;

(h) a step for preparing a starting material solution, comprising preparing a starting material solution containing riboflavin, an electron donor, and an aqueous solvent so that a riboflavin concentration C (μmol/L) is 0.1<C≦15.

(3) The method for producing superoxide according to (1) or (2), wherein the step for acquiring a flavin concentration comprises acquiring a concentration of flavin that is found similar by the similarity determination so that a purity of the superoxide in a radical to be generated is 75.6 to 100%.

(4) The method for producing superoxide according to any of (1) to (3), wherein the electron donor is EDTA.

(5) The method for producing superoxide according to any of (1) to (4), wherein the spin trap agent is CYPMPO.

(6) The method for producing superoxide according to any of (1) to (5), wherein the aqueous solvent is a phosphate buffer.

(7) A method for evaluating a superoxide scavenging ability of a sample, comprising the following steps (a), (b), (c), (d), (e), (i), (j), (k), and (l);

(a) a step for preparing a solution for determination, comprising preparing a solution for determination containing flavin, an electron donor, a spin trap agent, and an aqueous solvent,
(b) a step for generating a spin adduct/radical for determination, comprising generating a superoxide spin adduct, an electron donor radical spin adduct, and/or an electron donor radical by irradiating the solution for determination with light,
(c) a step for acquiring a spectrum for determination, comprising acquiring a spectrum by detecting the superoxide spin adduct, the electron donor radical spin adduct, and/or the electron donor radical thus generated by electron spin resonance,
(d) a step for determining similarity, comprising determining whether or not a standard spectrum of a superoxide spin adduct and the spectrum for determination are similar,
(e) a step for acquiring a flavin concentration, comprising acquiring a concentration of flavin that is found similar by the similarity determination,
(i) a step for preparing a solution for evaluation, comprising preparing a solution for evaluation containing flavin at the concentration as acquired above, an electron donor, a spin trap agent, a sample to be evaluated for its superoxide scavenging ability, and an aqueous solvent,
(j) a step for generating a spin adduct for evaluation, comprising generating a spin adduct by irradiating the solution for evaluation with light,
(k) a step for acquiring a spectrum for evaluation, comprising acquiring a spectrum by detecting the spin adduct for evaluation by electron spin resonance, and
(l) a step for comparative evaluation, comprising evaluating a superoxide scavenging ability by comparing a standard spectrum of a superoxide spin adduct with the spectrum for evaluation.

The method according to (7), wherein the method comprises the following step (m) instead of the steps (a), (b), (c), (d), (e), and (i), when flavin is riboflavin; (m) a step for preparing a solution for evaluation, comprising preparing a solution for evaluation containing riboflavin, an electron donor, a spin trap agent, a sample to be evaluated for its superoxide scavenging ability, and an aqueous solvent so that a riboflavin concentration C (μmol/L) is 0.1<C≦15.

(9) The method according to (7) or (8), wherein the step for acquiring a flavin concentration comprises acquiring a concentration of flavin that is found similar by the similarity determination so that a purity of the superoxide in a radical to be generated is 75.6 to 100%.

(10) The method according to any of (7) to (9), wherein the electron donor is EDTA.

(11) The method according to any of (7) to (10), wherein the spin trap agent is CYPMPO.

(12) The method according to any of (7) to (11), wherein the aqueous solvent is a phosphate buffer.

(13) A device for producing superoxide, comprising the following means (i), (ii), (iii), (iv), (v), (vi), and (vii);

(i) a means for preparing a solution for determination, comprising preparing a solution for determination containing flavin, an electron donor, a spin trap agent, and an aqueous solvent,
(ii) a means for generating a spin adduct/radical for determination, comprising generating a superoxide spin adduct, an electron donor radical spin adduct, and/or an electron donor radical by irradiating the solution for determination with light,
(iii) a means for acquiring a spectrum for determination, comprising acquiring a spectrum by detecting the superoxide spin adduct, the electron donor radical spin adduct, and/or the electron donor radical thus generated by electron spin resonance,
(iv) a means for determining similarity, comprising determining whether or not a standard spectrum of a superoxide spin adduct and the spectrum for determination are similar,
(v) a means for acquiring a flavin concentration, comprising acquiring a concentration of flavin that is found similar by the similarity determination,
(vi) a means for preparing a starting material solution, comprising preparing a starting material solution containing flavin at the concentration as acquired above, an electron donor, and an aqueous solvent, and
(vii) a means for generation, comprising generating superoxide by irradiating the starting material solution with light.

(14) The device for producing superoxide according to (13), wherein the device comprises the following means (viii) instead of the means (i), (ii), (iii), (iv), (v), and (vi), when flavin is riboflavin;

(viii) a means for preparing a starting material solution, comprising preparing a starting material solution containing riboflavin, an electron donor, and an aqueous solvent so that a riboflavin concentration C (μmol/L) is 0.1<C≦15.

(15) The device for producing superoxide according to (13) or (14), wherein the means for acquiring a flavin concentration comprises acquiring a concentration of flavin that is found similar by the similarity determination so that a purity of the superoxide in a radical to be generated is 75.6 to 100%.

(16) The device for producing superoxide according to any of (13) to (15), wherein the electron donor is EDTA.

(17) The device for producing superoxide according to any of (13) to (16), wherein the spin trap agent is CYPMPO.

(18) The device for producing superoxide according to any of (13) to (17), wherein the aqueous solvent is a phosphate buffer.

(19) A device for evaluating a superoxide scavenging ability of a sample, comprising the following means (i), (ii), (iii), (iv), (v), (ix), (x), (xi), and (xii);

(i) a means for preparing a solution for determination, comprising preparing a solution for determination containing flavin, an electron donor, a spin trap agent, and an aqueous solvent,
(ii) a means for generating a spin adduct/radical for determination, comprising generating a superoxide spin adduct, an electron donor radical spin adduct, and/or an electron donor radical by irradiating the solution for determination with light,
(iii) a means for acquiring a spectrum for determination, comprising acquiring a spectrum by detecting the superoxide spin adduct, the electron donor radical spin adduct, and/or the electron donor radical thus generated by electron spin resonance,
(iv) a means for determining similarity, comprising determining whether or not a standard spectrum of a superoxide spin adduct and the spectrum for determination are similar,
(v) a means for acquiring a flavin concentration, comprising acquiring a concentration of flavin that is found similar by the similarity determination,
(ix) a means for preparing a solution for evaluation, comprising preparing a solution for evaluation containing flavin at the concentration as acquired above, an electron donor, a spin trap agent, a sample to be evaluated for its superoxide scavenging ability, and an aqueous solvent,
(x) a means for generating a spin adduct for evaluation, comprising generating a spin adduct by irradiating the solution for evaluation with light,
(xi) a means for acquiring a spectrum for evaluation, comprising acquiring a spectrum by detecting the spin adduct for evaluation by electron spin resonance, and
(xii) a means for comparative evaluation, comprising evaluating a superoxide scavenging ability by comparing a standard spectrum of a superoxide spin adduct with the spectrum for evaluation.

(20) The device according to (19), wherein the device comprises the following means (xiii) instead of the means (i), (ii), (iii), (iv), (v), and (ix), when flavin is riboflavin;

(xiii) a means for preparing a solution for evaluation, comprising preparing a solution for evaluation containing riboflavin, an electron donor, a spin trap agent, a sample to be evaluated for its superoxide scavenging ability, and an aqueous solvent so that a riboflavin concentration C (μmol/L) is 0.1<C≦15.

(21) The device according to (19) or (20), wherein the means for acquiring a flavin concentration comprises acquiring a concentration of flavin that is found similar by the similarity determination so that a purity of the superoxide in a radical to be generated is 75.6 to 100%.

(22) The device according to any of (19) to (21), wherein the electron donor is EDTA.

(23) The device according to any of (19) to (22), wherein the spin trap agent is CYPMPO.

(24) The device according to any of (19) to (23), wherein the aqueous solvent is a phosphate buffer.

(25) A method for producing superoxide in vivo, comprising the following steps (A), (B), (C), (D), (E), (F), and (G);

(A) a step for administering a starting material, comprising administering arbitrary amounts of flavin, an electron donor, and a spin trap agent to a biological sample or into a body of a non-human animal,
(B) a step for generating a spin adduct/radical for determination, comprising generating a superoxide spin adduct, an electron donor radical spin adduct, and/or an electron donor radical by irradiating, with light, a part of the biological sample or the body of the non-human animal where the flavin, the electron donor, and the spin trap agent administered are present,
(C) a step for acquiring a spectrum for determination, comprising acquiring a spectrum by detecting the superoxide spin adduct, the electron donor radical spin adduct, and/or the electron donor radical thus generated by electron spin resonance,
(D) a step for determining similarity, comprising determining whether or not a standard spectrum of a superoxide spin adduct and the spectrum for determination are similar,
(E) a step for acquiring an optimal amount of flavin, comprising acquiring an optimal amount of flavin that is found similar by the similarity determination,
(F) a step for administering an optimal starting material, comprising administering the optimal amount of flavin acquired above and an electron donor to a biological sample or into a body of the non-human animal, and
(G) a step for generating superoxide, comprising irradiating, with light, a part of the biological sample or the body of the non-human animal where the flavin and the electron donor administered are present.

(26) The method for producing superoxide in vivo according to (25), wherein the electron donor is EDTA.

(27) The method for producing superoxide in vivo according to (25) or (26), wherein the spin trap agent is CYPMPO.

(28) A method for evaluating a superoxide scavenging ability in vivo, comprising the following steps (A), (B), (C), (D), (E), (H), (I), (J), and (K), wherein the method is for evaluating a superoxide scavenging ability of a sample in vivo;

(A) a step for administering a starting material, comprising administering arbitrary amounts of flavin, an electron donor, and a spin trap agent to a biological sample or into a body of a non-human animal,
(B) a step for generating a spin adduct/radical for determination, comprising generating a superoxide spin adduct, an electron donor radical spin adduct, and/or an electron donor radical by irradiating, with light, the part of the biological sample or the body of the non-human animal where the flavin, the electron donor, and the spin trap agent administered are present,
(C) a step for acquiring a spectrum for determination, comprising acquiring a spectrum by detecting the superoxide spin adduct, the electron donor radical spin adduct, and/or the electron donor radical thus generated by electron spin resonance,
(D) a step for determining similarity, comprising determining whether or not a standard spectrum of a superoxide spin adduct and the spectrum for determination are similar,
(E) a step for acquiring an optimal amount of flavin, comprising acquiring an optimal amount of flavin that is found similar by the similarity determination,
(H) a step for administering a specimen for evaluation, comprising administering a specimen for evaluation containing the optimal amount of flavin acquired above, an electron donor, a spin trap agent, and a sample to be evaluated for its superoxide scavenging ability to the biological sample or into a body of a non-human animal,
(I) a step for generating a spin adduct in vivo, comprising generating a spin adduct by irradiating, with light, the administered specimen for evaluation in the biological sample or the body of the non-human animal,
(J) a step for acquiring a spectrum in vivo, comprising acquiring a spectrum by detecting the spin adduct by electron spin resonance, and
(K) an in vivo comparative evaluation step, comprising evaluating a superoxide scavenging ability by comparing a standard spectrum of a superoxide spin adduct with the spectrum acquired as above.

(29) The method for evaluating a superoxide scavenging ability in vivo according to (28), wherein the electron donor is EDTA.

(30) The method for evaluating a superoxide scavenging ability in vivo according to (28) or (29), wherein the spin trap agent is CYPMPO.

### ADVANTAGEOUS EFFECTS OF INVENTION

The present invention enables simple and stable production of superoxide or a radical containing superoxide at a high purity by selectively generating superoxide or a radical containing superoxide at a high purity either ex vivo or in vivo. This allows evaluation and research on the association of superoxide with disease and symptoms of aging to be carried out in an accurate and simple way, promoting the quest for therapeutic and preventive methods for diseases and symptoms of aging involving superoxide as well as elucidation of mechanisms of the process of such diseases and symptoms of aging. Further, because the present invention enables simple evaluation of the superoxide scavenging ability of the sample of interest either ex vivo or in vivo, it allows one to pursue the quest for an antioxidant that is truly efficacious for the living body as well as to evaluate the antioxidant ability of various substances in an accurate, simple, and rapid way.

### BRIEF DESCRIPTION OF THE DRAWINGS

FIG. 1 is a diagram showing one embodiment of a device for producing superoxide according to the present invention.

FIG. 2 is a functional block diagram showing a function of each component of a device for producing superoxide 1 according to the present embodiment.

FIG. 3 is a diagram showing a means for preparing a solution for determination 2 according to the present embodiment.

FIG. 4 is a diagram showing a means for acquiring a spectrum for determination 4 according to the present embodiment.

FIG. 5 is a diagram showing a means for determining similarity 5 according to the present embodiment.

FIG. 6 is a diagram showing a means for preparing a starting material solution 7 according to the present embodiment.

FIG. 7 is a diagram showing one embodiment of a device for evaluating the superoxide scavenging ability according to the present invention.

FIG. 8 is a functional block diagram showing the function of each component of a device for evaluating the superoxide scavenging ability 9 according to the present embodiment.

FIG. 9 is a diagram showing a means for preparing a solution for evaluation 10 according to the present embodiment.

FIG. 10 is a diagram showing a spectrum obtained by irradiating, with visible light, an SOD-free aqueous solution and an aqueous solution with added SOD, and then measuring by Electron Spin Resonance (ESR). In the figure, the spectrum A indicates a spectrum obtained from an SOD-free aqueous solution and the spectrum B indicates a spectrum obtained from an aqueous solution with added SOD.

FIG. 11 shows a spectrum of a spin adduct composed of superoxide and CYPMPO obtained by computer simulation (standard spectrum of superoxide) (top) and a spectrum of an EDTA radical obtained by computer simulation (standard spectrum of an EDTA radical) (bottom).

FIG. 12 is a diagram showing a spectrum obtained by irradiating, with visible light, an aqueous solution prepared using riboflavin as a redox reaction catalyst and tetramethylethylenediamine (TMD) as an electron donor, and then measuring by ESR.

FIG. 13 is a diagram showing a spectrum obtained by irradiating, with visible light, an aqueous solution prepared using riboflavin as a redox reaction catalyst and methionine as an electron donor, and then measuring by ESR.

FIG. 14 is a diagram showing a spectrum obtained by irradiating, with visible light, an aqueous solution prepared using FMN as a redox reaction catalyst and EDTA as an electron donor, and then measuring by ESR.

FIG. 15 shows a spectrum obtained by irradiating, with visible light, an aqueous solution prepared using FMN as a redox reaction catalyst and TMD as an electron donor, and then measuring by ESR.

FIG. 16 is a diagram showing a spectrum obtained by irradiating, with visible light, an aqueous solution prepared using fluorescein as a redox reaction catalyst and methionine as an electron donor, and then measuring by ESR.

FIG. 17 is a graph showing the results obtained by specifying and quantifying the radical generated by irradiating aqueous solutions with various concentrations of riboflavin with visible light, and then calculating the purity of superoxide in the radical thus generated. In the graph, the vertical axis and horizontal axis indicate the amount of radicals generated and the concentration of riboflavin, respectively.

FIG. 18 is a graph showing the signal intensity of the spectrum obtained by measuring aqueous solutions that were irradiated with visible light for different lengths of time by ESR. In the graph, the vertical axis indicates the signal intensity and the horizontal axis indicates the time of irradiation of visible light or the time after discontinuation of irradiation of visible light.

FIG. 19 is a graph showing the radical generation-inhibitory rate of SOD in the generation of superoxide by light irradiation of riboflavin and in the generation of superoxide by xanthine oxidase. In the graph, the vertical axis indicates the radical generation-inhibitory rate and the horizontal axis indicates the SOD concentration added.

### DETAILED DESCRIPTION OF THE INVENTION

Hereinbelow, a method for producing superoxide, a method for evaluating the superoxide scavenging ability, a device for producing superoxide, and a device for evaluating the superoxide scavenging ability according to the present invention will be described in detail.

First of all, the method for producing superoxide according to the present invention comprises the following steps (a), (b), (c), (d), (e), (f), and (g);

(a) a step for preparing a solution for determination, comprising preparing a solution for determination containing flavin, an electron donor, a spin trap agent, and an aqueous solvent,
(b) a step for generating a spin adduct/radical for determination, comprising generating a superoxide spin adduct, an electron donor radical spin adduct, and/or an electron donor radical by irradiating the solution for determination with light,
(c) a step for acquiring a spectrum for determination, comprising acquiring a spectrum by detecting the superoxide spin adduct, the electron donor radical spin adduct, and/or the electron donor radical thus generated by electron spin resonance,
(d) a step for determining similarity, comprising determining whether or not a standard spectrum of a superoxide spin adduct and the spectrum for determination are similar,
(e) a step for acquiring a flavin concentration, comprising acquiring a concentration of flavin that is found similar by the similarity determination,
(f) a step for preparing a starting material solution, comprising preparing a starting material solution containing flavin at the concentration as acquired above, an electron donor, and an aqueous solvent, and
(g) a step for generation, comprising generating superoxide by irradiating the starting material solution with light.

In the present embodiment, “a radical containing superoxide at a high purity” refers an aggregation of radicals composed of superoxide and an electron donor radical (interfering radical or TH. radical), in which the proportion of superoxide (purity of superoxide) is sufficiently greater than the proportion of radicals other than superoxide. The purity is preferably 70% or more and less than 100%, more preferably 75.6% or more and less than 100%, and even more preferably 83.3% or more and less than 100%.

It should be noted that the purity of superoxide in a superoxide-containing radical can be calculated according to a routine method. For example, first of all, a superoxide-containing radical is generated in an aqueous solution. Then, the solution is measured by electron spin resonance to obtain a spectrum that is similar to the standard spectrum of superoxide, based on which the amount of superoxide generated is measured. Subsequently, superoxide dismutase (SOD), which is an enzyme that specifically scavenges superoxide, is added to an aqueous solution having a similar composition to the aqueous solution in which the amount of superoxide generated has been measured, and a radical is generated in this aqueous solution. Then, the aqueous solution is measured by electron spin resonance to obtain a spectrum, based on which the amount of electron donor radical (interfering radical or TH. radical) generated is measured. Subsequently, from the measured amounts of superoxide and electron donor radical (interfering radical or TH. radical) generated, the purity of superoxide can be calculated by the following formula 1.

Here, Electron Spin Resonance (ESR) is a kind of method used for identification and quantification of radicals. In electron spin resonance, a sample is placed in a magnetic field, which is exposed to microwaves to cause resonance of the unpaired electron of the radical in the sample, and the absorption of energy when the resonance takes place is measured. The absorption of energy is measured while varying the magnetic field in order to obtain a series of energy absorption changes as a spectrum. Because the shape of a spectrum is determined according to the kind of radical, the radical contained in the sample can be identified by observing the shape of the spectrum thus obtained.

Purity of superoxide (%)={amount of superoxide generated/(amount of superoxide generated+amount of an electron donor radical (interfering radical or TH. radical) generated)}×100 (Formula 1)

In the present invention, the standard spectrum of a superoxide spin adduct (the standard spectrum of superoxide) refers to a spectrum obtained by measuring a superoxide spin adduct, a spin adduct of a radical containing superoxide at a high purity, or a mixture of a spin adduct of a radical containing superoxide at a high purity and a radical by electron spin resonance, or a spectrum that is assumed to be obtained by measuring the aforementioned substances by electron spin resonance. The standard spectrum of superoxide can be obtained, for example, by computer simulation, and one described in the previously reported literature (MASATO K. et al., Free Radical Research, Vol. 40, No. 11, pages 1166 to 1172, 2006) can be used. In addition, the standard spectrum of superoxide can also be obtained by generating a radical containing superoxide at a high purity using xanthine oxidase, and then measuring it by electron spin resonance.

Step (a): In the step for preparing a solution for determination, a solution for determination can be prepared by dissolving flavin, an electron donor, and a spin trap agent in an aqueous solvent. So long as its characteristics are not impaired, the solution for determination can also contain other substances.

Flavin refers to a group of derivatives of dimethylisoalloxazine with a substituent on the 10-position. As will be shown in the following formulae 2 and 3, flavin is excited to a state of a higher order of energy when irradiated with light in the co-presence of an electron donor, converting into a flavin radical by receiving one electron from the electron donor. At the time same, the electron donor that donated one electron now has an unpaired electron, becoming an electron donor radical (interfering radical or TH. radical) (Formula 2). Subsequently, the flavin radical adds one electron to the oxygen molecule to generate superoxide (Formula 3).

Flavin+Electron donor+Light→Flavin radical+Electron donor radical (Formula 2)

Flavin radical+Oxygen molecule→Superoxide+Flavin (Formula 3)

The present invention enables the production of superoxide or a radical containing superoxide at a high purity by utilizing the aforementioned reactions. Examples of flavin that can be used in the present invention include riboflavin, flavin mononucleotide (FMN), isoalloxazine, alloxazine, lumichrome, lumiflavin, flavin-adenine dinucleotide (FAD), galactoflavin, D-araboflavin, lyxoflavine, and any combination of these flavins. Among them, riboflavin, FMN, or a mixture thereof can be preferably used.

Also, the electron donor used in the present invention may be a substance having a low redox potential that donates an electron to the excited flavin. Examples of the electron donor include an oxygen-containing compound, a nitrogen-containing compound, a phosphorus-containing compound, and a sulfur-containing compound. Among them, a nitrogen-containing compound is preferred. Examples of such a nitrogen-containing compound include ethylenediaminetetraacetate (EDTA), methionine, and tetramethylethylenediamine (TMD), among which EDTA is preferably used.

The spin trap agent is a reagent that produces a stable spin adduct by covalently binding to an unstable radical (to form an adduct), which would be instantly converted into a different substance otherwise. Because superoxide is also an unstable radical, it is difficult to directly detect it by electron spin resonance; however, detection of superoxide becomes possible by producing a spin adduct. The spin trap agent used in the present invention may be at least one that produces a spin adduct with superoxide, and examples thereof include 2-(5,5-dimethyl-2-oxo-2λ5-[1,3,2]dioxaphosphinan-2-yl)-2-methyl-3,4-dihydro-2H-pyrrole 1-oxide (CYPMPO), 5,5-dimethyl-1-pyrroline N-oxide (DMPO), 5-diethoxyphosphoryl 5-methyl-1-pyrroline N-oxide (DEPMPO), 2,5,5-triethyl-1-pyrroline N-Oxide (M₃PO), and 3,3,5,5-tetramethyl-1-pyrroline N-Oxide (TMPO), among which CYPMPO is preferably used.

Also, the aqueous solvent used in the present invention is not particularly limited so long as it has a function of keeping the pH of a solution containing the aqueous solvent constant. Examples of the aqueous solvent include a phosphate buffer, an acetate buffer, a citrate buffer, a borate buffer, a tartrate buffer, and a tris buffer, among which a phosphate buffer can be preferably used.

Step (b): In the step for generating a spin adduct/radical for determination, light irradiation of the solution for determination can be performed using an appropriate light source. Examples of the light source used in the present invention include a xenon lamp, a fluorescent lamp, a halogen lamp, a krypton lamp, a sodium lamp, a mercury lamp, and a metal halide lamp. It should be noted that the kind of light (wavelength), intensity of light, irradiation time, etc. employed in the present invention are not particularly limited and these parameters can be appropriately set according to conditions such as the kind of light source, a positional relationship between the light source and the object to be irradiated, the quantity of the object to be irradiated, the concentration of the object to be irradiated, and the necessary amount of superoxide to be generated as a result of irradiation.

Also, in Step (b): A step for generating a spin adduct/radical for determination, when the solution for determination is irradiated with light, an electron donor radical (interfering radical or TH. radical) and superoxide are produced by the reactions shown in the formulae 2 and 3, respectively. The superoxide thus produced is covalently bound to the spin trap agent in the solution for determination, thereby generating a superoxide spin adduct. Also, when the spin trap agent in the solution for determination is the one that forms a spin adduct with an electron donor radical (interfering radical or TH. radical), a spin adduct of an electron donor radical (interfering radical or TH. radical) is generated.

Step (c): In the step for acquiring a spectrum for determination, detection of a superoxide spin adduct, a spin adduct of an electron donor radical (interfering radical or TH. radical), and/or an electron donor radical (interfering radical or TH. radical) by electron spin resonance and acquisition of a spectrum (a spectrum for determination) can be carried out according to a routine method. For example, it can be performed using a commercially available ESR measuring device such as JES-RE1X (JEOL Ltd.). Also, since an electron donor radical (interfering radical or TH. radical) is generally relatively stable and has a long life, it can be detected by electron spin resonance when either it forms a spin adduct, or it is not forming a spin adduct.

Step (d): In the step for determining similarity, determination of whether or not the standard spectrum of superoxide is similar to the spectrum for determination can be made, for example, by displaying the standard spectrum of superoxide and the spectrum for determination side by side or by superimposing them and making a visual observation. Determination can also be made by computer processing using a shape comparison program and the like.

Here, in the present invention, the cases in which a plurality of spectra are “similar” or “in a similarity relationship” encompass not only a case in which a plurality of spectra are related in such a way that they are shrunk or enlarged relative to each other, but also a case in which a plurality of spectra share a high homology in their shapes. The “high homology” as used herein refers to a homology of at least 70%, preferably a homology of 80% or more, more preferably a homology of 85% or more, even more preferably a homology of 90% or more, and still even more preferably a homology of 95% or more.

Step (e): In the step for acquiring a flavin concentration, it might be necessary to meet the conditions that when a spectrum for determination that is considered to be similar to the standard spectrum of superoxide is obtained by the step (d), the flavin concentration of the solution for determination from which the spectrum for determination is obtained is acquired. That is, according to the step (e), when the determination is made in the step (d) that the standard spectrum of superoxide and the spectrum for determination are not similar, a solution for determination is once again prepared with a varied concentration of flavin in the step (a), and the subsequent steps (b)→(c)→(d) are carried out. Namely, the determination process by the steps (a) to (d) is repeated as needed until a spectrum for determination that is similar to the standard spectrum of superoxide is obtained, and therefore, the desired concentration of flavin can be obtained in the end.

Also, in the step (e): The step for acquiring a flavin concentration, the concentration of flavin that is considered to be similar by the similarity determination can be obtained so that the purity of superoxide in a radical to be generated is in a range of 75.6 to 100%.

Step (f): In the step for preparing a starting material solution, the starting material solution can be prepared by dissolving flavin and an electron donor in an aqueous solvent. The starting material solution is prepared so as to have the same flavin concentration as obtained in the step (e). It should be noted that in the present invention the starting material solution may also contain other substances so long as its characteristics are not impaired.

Step (g): In the step for generation, light irradiation of the starting material solution can be performed by a similar method to the aforementioned light irradiation of the solution for determination in the step (b).

Also, when flavin is riboflavin, the method for producing superoxide according to the present invention can include, instead of the aforementioned steps (a), (b), (c), (d), (e), and (f), the step (h): “a step for preparing a starting material solution, comprising preparing a starting material solution containing riboflavin, an electron donor, and an aqueous solvent so that a riboflavin concentration C (μmol/L) is 0.1<C≦15.” As will be demonstrated in Examples later, when radicals are generated by irradiating, with light, a starting material solution containing riboflavin, an electron donor, and an aqueous solvent so that the riboflavin concentration C (μmol/L) is 0.1<C≦15, radicals in which the purity of superoxide is 75.6% to 100% can be produced. Further, when radicals are generated by irradiating, with light, a starting material solution containing riboflavin, an electron donor, and an aqueous solvent so that the riboflavin concentration C (μmol/L) is 0.1<C≦10, radicals in which the purity of superoxide is 83.3% to 100% can be produced.

Next, the method for evaluating the superoxide scavenging ability according to the present invention is a method for evaluating the superoxide scavenging ability of a sample, comprising the following steps (a), (b), (c), (d), (e), (i), (j), (k), and (l);

(a) a step for preparing a solution for determination, comprising preparing a solution for determination containing flavin, an electron donor, a spin trap agent, and an aqueous solvent,
(b) a step for generating a spin adduct/radical for determination, comprising generating a superoxide spin adduct, an electron donor radical spin adduct, and/or an electron donor radical by irradiating the solution for determination with light,
(c) a step for acquiring a spectrum for determination, comprising acquiring a spectrum by detecting the superoxide spin adduct, the electron donor radical spin adduct, and/or the electron donor radical thus generated by electron spin resonance,
(d) a step for determining similarity, comprising determining whether or not a standard spectrum of a superoxide spin adduct and the spectrum for determination are similar,
(e) a step for acquiring a flavin concentration, comprising acquiring a concentration of flavin that is found similar by the similarity determination,
(i) a step for preparing a solution for evaluation, comprising preparing a solution for evaluation containing flavin at the concentration as acquired above, an electron donor, a spin trap agent, a sample to be evaluated for its superoxide scavenging ability, and an aqueous solvent,
(j) a step for generating a spin adduct for evaluation, comprising generating a spin adduct by irradiating the solution for evaluation with light,
(k) a step for acquiring a spectrum for evaluation, comprising acquiring a spectrum by detecting the spin adduct for evaluation by electron spin resonance, and
(l) a step for comparative evaluation, comprising evaluating a superoxide scavenging ability by comparing a standard spectrum of a superoxide spin adduct with the spectrum for evaluation.

It should be noted that the steps (a), (b), (c), (d), and (e) are carried out in a similar manner to the method for producing superoxide according to the present invention.

Step (i): In the step for preparing a solution for evaluation, the solution for evaluation is prepared by dissolving flavin, an electron donor, a spin trap agent, and a sample to be evaluated for its superoxide scavenging ability in an aqueous solvent. The solution for evaluation is prepared so as to have the same flavin concentration as obtained in the step (e). It should be noted that in the present invention the solution for evaluation may also contain other substances so long as its characteristics are not impaired.

Examples of the sample to be evaluated for its superoxide scavenging ability in the present invention include foods and plant extracts, and compounds such as cosmetic compositions and pharmaceutical compositions. These samples to be evaluated are evaluated to have a “scavenging ability” when they scavenge superoxide before it is converted into a spin adduct.

Step (j): In the step for generating a spin adduct for evaluation, light irradiation of the solution for evaluation can be performed by a similar method to the aforementioned light irradiation of the solution for determination in the steps (b) and (g).

Step (k): In the step for acquiring a spectrum for evaluation, detection of a spin adduct for evaluation by electron spin resonance and acquisition of a spectrum (spectrum for evaluation) can be performed by a similar method to the method employed in the aforementioned step (c).

Step (l): In the step of comparative evaluation, comparison of the standard spectrum of superoxide with the spectrum for evaluation can be performed, for example, by a similar method to the method employed in the aforementioned step (d). Also, as to the evaluation of the superoxide scavenging ability of a sample, a sample of interest is evaluated as “having the superoxide scavenging ability” when the signal intensity of the spectrum for evaluation is smaller than the signal intensity of the standard spectrum of superoxide, which indicates disappearance of superoxide. Meanwhile, a sample of interest is evaluated as “not having the superoxide scavenging ability” when there is only a little difference in signal intensity between the spectrum for evaluation and the standard spectrum of superoxide, which indicates failure of elimination of superoxide. That is, a reduction in the signal intensity of the spectrum for evaluation and the antioxidant ability of the sample are in a proportional relationship relative to each other, and when the sample is an antioxidative substance, the signal intensity of the spectrum for evaluation is reduced compared to that of the standard spectrum of superoxide, whereas when the sample is a non-antioxidative substance, the signal intensity of the spectrum for evaluation is almost the same as that of the standard spectrum of superoxide.

Also, when flavin is riboflavin, the method for evaluating the superoxide scavenging ability according to the present invention can include, instead of the aforementioned steps (a), (b), (c), (d), (e), and (i), the step (m): “a step for preparing a solution for evaluation, comprising preparing a solution for evaluation containing riboflavin, an electron donor, a spin trap agent, a sample to be evaluated for its superoxide scavenging ability, and an aqueous solvent so that a riboflavin concentration C (μmol/L) is 0.1<C≦15.”

Next, the present invention provides a device for producing superoxide. The device for producing superoxide according to the present invention comprises the following means (i), (ii), (iii), (iv), (v), (vi), and (vii);

(i) a means for preparing a solution for determination, comprising preparing a solution for determination containing flavin, an electron donor, a spin trap agent, and an aqueous solvent,
(ii) a means for generating a spin adduct/radical for determination, comprising generating a superoxide spin adduct, an electron donor radical spin adduct, and/or an electron donor radical by irradiating the solution for determination with light,
(iii) a means for acquiring a spectrum for determination, comprising acquiring a spectrum by detecting the superoxide spin adduct, the electron donor radical spin adduct, and/or the electron donor radical thus generated by electron spin resonance,
(iv) a means for determining similarity, comprising determining whether or not a standard spectrum of a superoxide spin adduct and the spectrum for determination are similar,
(v) a means for acquiring a flavin concentration, comprising acquiring a concentration of flavin that is found similar by the similarity determination,
(vi) a means for preparing a starting material solution, comprising preparing a starting material solution containing flavin at the concentration as acquired above, an electron donor, and an aqueous solvent, and
(vii) a means for generation, comprising generating superoxide by irradiating the starting material solution with light.

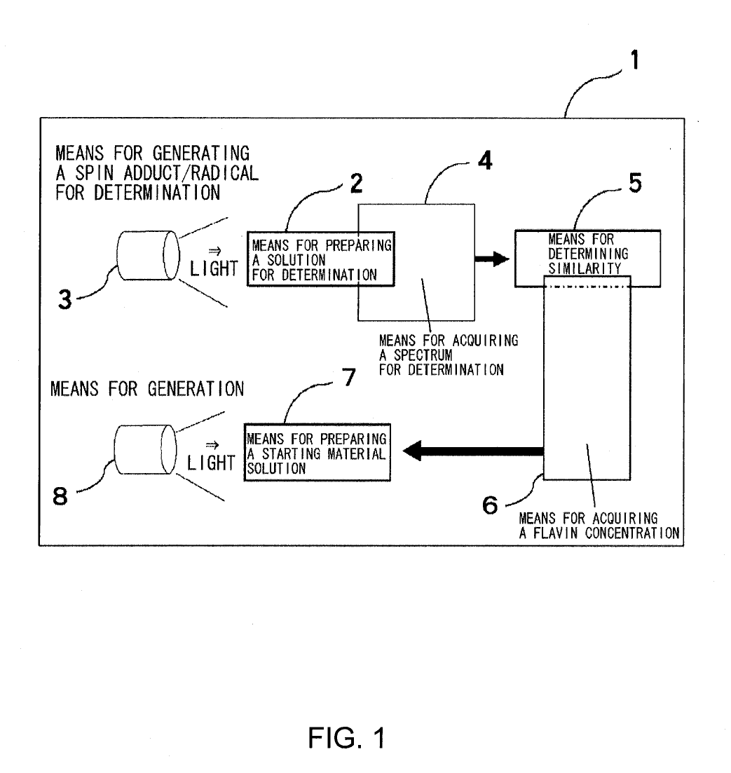

One embodiment of the device for producing superoxide according to the present invention will be explained with reference to the drawings. FIG. 1 is a schematic diagram illustrating the basic configuration of the device for producing superoxide 1 according to the present embodiment. As shown in FIG. 1, the device for producing superoxide 1 is mainly composed of a means for preparing a solution for determination 2, a means for generating a spin adduct/radical for determination 3, a means for acquiring a spectrum for determination 4, a means for determining similarity 5, a means for acquiring a flavin concentration 6, a means for preparing a starting material solution 7, and a means for generation 8.

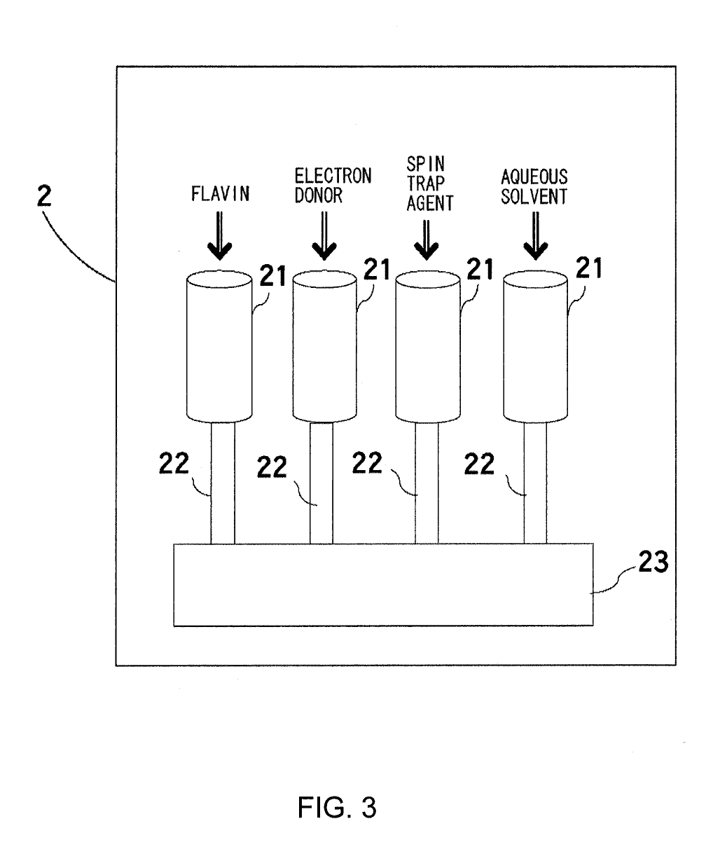

The means for preparing a solution for determination 2 may have such a configuration or function that properly prepares a solution for determination containing flavin, an electron donor, a spin trap agent, and an aqueous solvent. Examples of such a configuration include, as shown in FIG. 3, a configuration in which an injection pipe for determination 22, which is inserted through a solution for determination container unit 23, is formed, and a plurality of containers for determination with an injection volume-regulatory function 21 are disposed according to the number of substances to be injected. In this configuration, from each of the injection pipes for determination 22 of the containers for determination with an injection volume-regulatory function 21 each containing flavin, an electron donor, a spin trap agent, or an aqueous solvent, the appropriate amounts of flavin, electron donor, spin trap agent, and aqueous solvent can be injected into the solution for determination container unit 23, thereby preparing a solution for determination.

It should be noted that the means for preparing a solution for determination 2 is configured so as to be controllable by a control signal outputted from a control signal output unit 62 to be described later. Also, the solution for determination container unit 23 may be composed of, for example, a container formed to hold a liquid. In the present invention, as a material composing the container, ones that are highly transparent, water resistant, corrosion resistant, and drug resistant are preferred. Examples of such a material include glass and plastic.

Next, the means for generating a spin adduct/radical for determination 3 may have such a configuration or function that properly irradiates the solution for determination with light. As such a configuration, for example, it may be composed of a light source such as a xenon lamp, a fluorescent lamp, a halogen lamp, a krypton lamp, a sodium lamp, a mercury lamp, and a metal halide lamp, which are exemplified in the aforementioned step (b) of the method for producing superoxide.

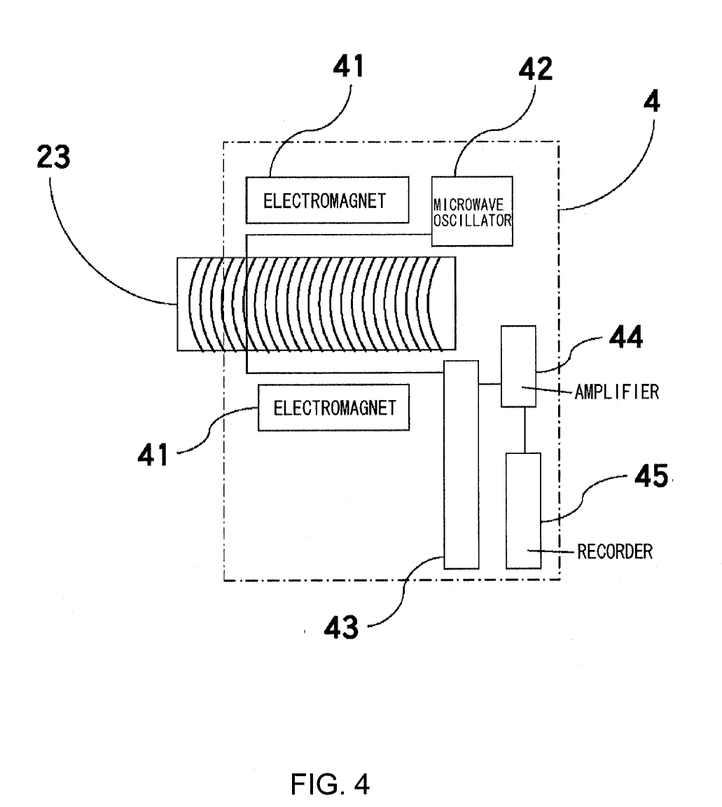

Next, the means for acquiring a spectrum for determination 4 may have such a configuration or function that detects a superoxide spin adduct, a spin adduct of an electron donor radical (interfering radical or TH. radical), and/or an electron donor radical (interfering radical or TH. radical) obtained by light irradiation of the solution for determination by electron spin resonance to obtain spectra of these substances. Examples of such a configuration include, as shown in FIG. 4, an electromagnet 41, a microwave oscillator 42, a crystalline diode detector 43, an amplifier 44, and a recorder 45. In this configuration, the solution for determination container unit 23 is placed in a magnetic field generated by the electromagnet 41, where it is exposed to microwaves by the microwave oscillator 42 to cause resonance of the unpaired electron of a spin adduct contained in the solution for determination, and the resulting absorption of energy is detected by the crystalline diode detector 43. Then, the signal thus detected is amplified by the amplifier 44 and then recorded by the recorder 45, thereby acquiring a spectrum for determination. Also, the means for acquiring a spectrum for determination 4 may be configured, for example, according to a commercially available ESR measuring device such as JES-RE1X (JEOL Ltd.).

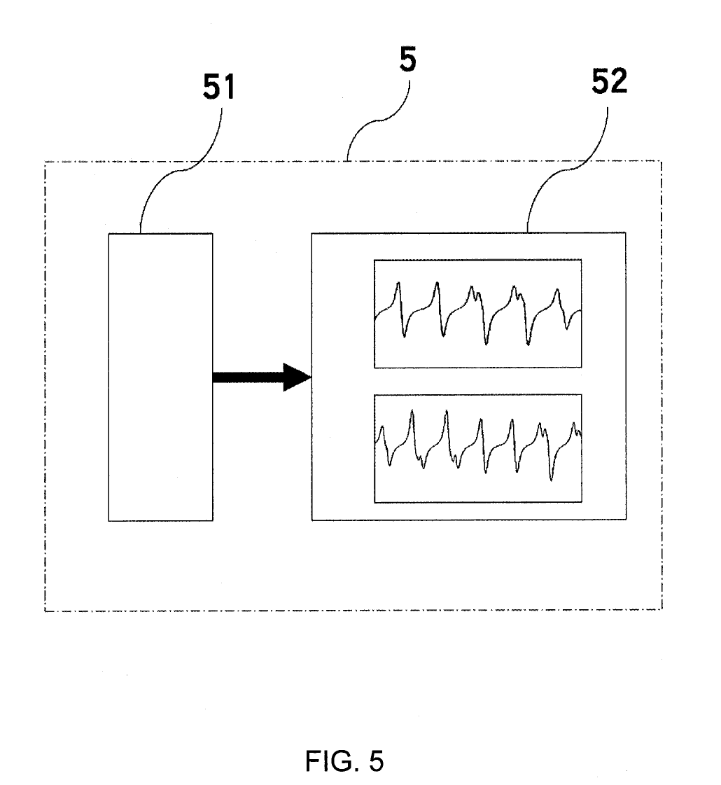

Next, the means for determination similarity 5 may have such a configuration or function that determines whether or not the spectrum for determination obtained as above is similar to the standard spectrum of superoxide. Examples of such a configuration include, as shown in FIG. 5, a configuration composed of an input unit 51 for inputting data of a spectrum and a display unit 52 for displaying the inputted data. In this configuration, whether or not the spectrum for determination obtained as above is similar to the standard spectrum of superoxide can be determined by inputting the data of the standard spectrum of superoxide and the data of the spectrum for determination in the input unit 51 and displaying these spectra on the display unit 52, and then comparing both shapes.

Next, the means for acquiring a flavin concentration 6 may have such a configuration or function that acquires, when a spectrum for determination that is considered to be similar to the standard spectrum of superoxide by the means for determining similarity 5 is obtained, the flavin concentration of the solution for determination from which the spectrum for determination is obtained. That is, according to the means for acquiring a flavin concentration 6, when the determination is made that the standard spectrum of superoxide and the spectrum for determination are not similar by the means for determining similarity 5, a solution for determination having a varied concentration of flavin is once again prepared by the means for preparing a solution for determination 2, and subsequently, a determination process including the means for generating a spin adduct/radical for determination 3→the means for acquiring a spectrum for determination 4→the means for determining similarity 5 is repeated until a spectrum for determination that is similar to the standard spectrum of superoxide is acquired, and therefore, the desired concentration of flavin can be obtained in the end.

Also, according to the means for acquiring a flavin concentration 6, the concentration of flavin that is considered to be similar by the similarity determination can be obtained so that the purity of superoxide in a radical to be generated is in a range of 75.6 to 100%.

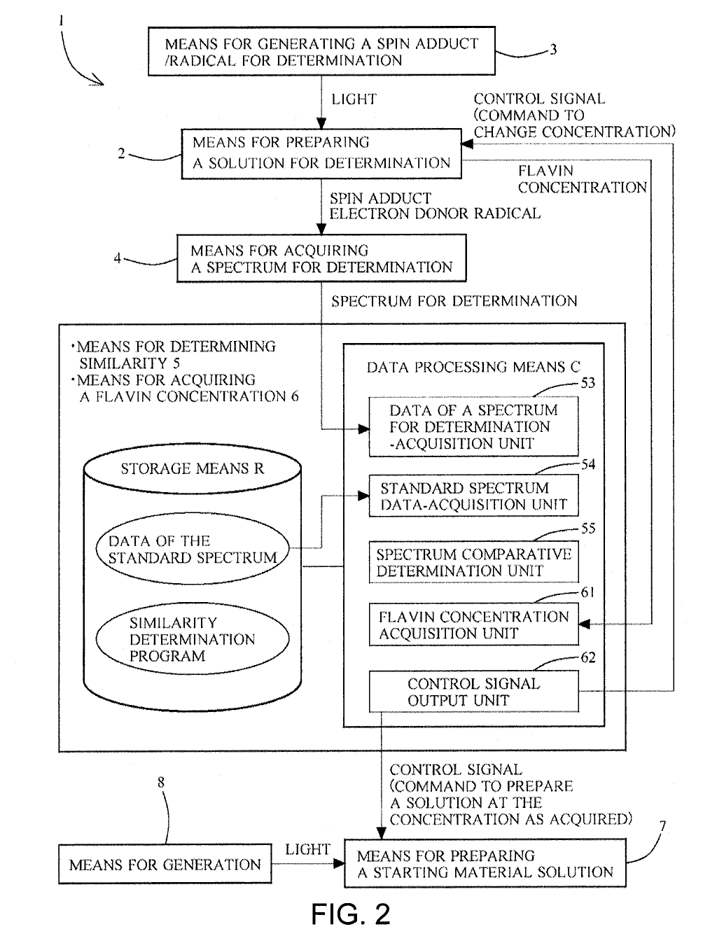

The aforementioned means for determining similarity 5 and the means for acquiring a flavin concentration 6 may be, for example, configured by a personal computer, etc. Specifically, as shown in FIG. 2, the above means are composed of a storage means R for storing a similarity determining program for executing the aforementioned similarity determination process and flavin concentration acquisition process, various data necessary for the similarity determination, and the like, and a data processing means C for processing data by acquiring various data from this storage means R and the means for acquiring a spectrum for determination 4. Hereinbelow, each component means will be explained.

The storage means R is composed of Read Only Memory (ROM), Random Access Memory (RAM), Hard Disk Drive (HDD), flash memory, and the like. It stores various kinds of data, while functioning as a working area when the data processing means C performs data processing.

According to the present embodiment, as shown in FIG. 2, a similarity determining program is installed in the storage means R, and the computer is configured to perform a function as each component to be described later when the data processing means C executes the similarity determining program. It should be noted that the utility form of the similarity determining program is not limited to the aforementioned configuration, and the program may be stored in recording media such as CD-ROM and directly started and executed from these recording media as well.

Also, the storage means R stores the data of the standard spectrum, which serves as a basis for determination of similarity. The data of the standard spectrum are, for example, the data acquired by computer simulation or from the previous reports that have been compiled into a database as described above.

Next, the data processing means C is composed of Central Processing Unit (CPU) and so on, and it is configured to function as a data of a spectrum for determination-acquisition unit 53, a standard spectrum data-acquisition unit 54, a spectrum comparative determination unit 55, a flavin concentration acquisition unit 61, and a control signal output unit 62 as shown in FIG. 2 upon execution of the similarity determining program installed in the storage means R. Hereinbelow, each of these components will be explained further in detail.

The data of a spectrum for determination-acquisition unit 53 acquires the spectrum for determination obtained by the means for acquiring a spectrum for determination 4 as data. For example, it may be configured so that the spectrum for determination recorded in the recorder 45 is converted into digital data and then inputted by the input unit 51, which is composed of a certain interface.

The standard spectrum data-acquisition unit 54 retrieves to acquire the data of the standard spectrum stored in the storage means R.

The spectrum comparative determination unit 55 determines whether or not the spectrum for determination is similar to the standard spectrum by comparing them. Specifically, the spectrum comparative determination unit 55 acquires the data of the spectrum for determination obtained by the data of the spectrum for determination-acquisition unit 53 and the data of the standard spectrum obtained by the standard spectrum data-acquisition unit 54, compares both data, and based on certain conditions of similarity, determines whether or not they are similar. Thereafter, the results of determination thus obtained are outputted to the control signal output unit 62.

The flavin concentration acquisition unit 61 acquires the flavin concentration of the solution for determination prepared by the means for preparing a solution for determination 2. According to the present embodiment, when the determination is made that the spectrum for determination and the standard spectrum are similar by the spectrum comparative determination unit 55, the flavin concentration acquisition unit 61 acquires the flavin concentration of the solution for determination measured by a certain concentration measuring device as data.

The control signal output unit 62 outputs a control signal to the means for preparing a solution for determination 2 or to the means for preparing a starting material solution 7. When the control signal output unit 62 according to the present embodiment receives, from the spectrum comparative determination unit 55, the determination result that the spectrum for determination and the standard spectrum are not similar, it sends a control signal to the means for preparing a solution for determination 2 to readjust a solution for determination by varying the concentration of flavin. Meanwhile, when the control signal output unit 62 receives the determination result that the spectrum for determination and the standard spectrum are similar, it sends a control signal to the means for preparing a starting material solution 7 to prepare a starting material solution based on the flavin concentration obtained by the flavin concentration acquisition unit 61.

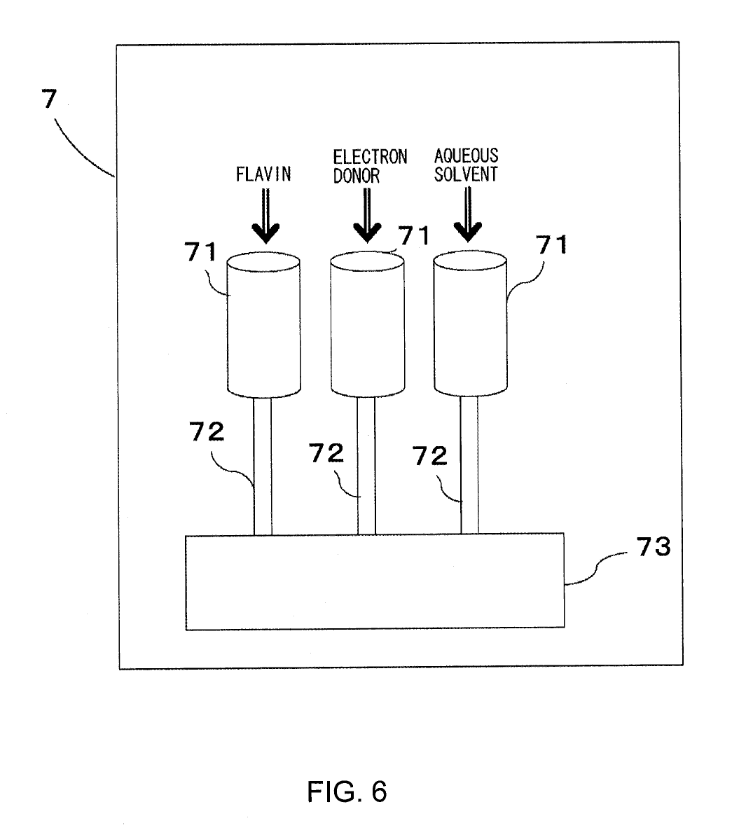

Next, the means for preparing a starting material solution 7 may have such a configuration or function that property prepares a starting material solution containing flavin, an electron donor, and an aqueous solvent. Examples of such a configuration include a configuration in which, as shown in FIG. 6, a starting material injection pipe 72, which can be inserted through a starting material container unit 73, is formed, and a plurality of starting material containers with an injection volume-regulatory function 71 are disposed according to the number of substances to be injected. In this configuration, from each of the starting material injection pipes 72 of the starting material containers with an injection volume-regulatory function 71 each containing flavin, an electron donor, and an aqueous solvent, the appropriate amounts of flavin, electron donor, and aqueous solvent are injected into the starting material container unit 73, thereby preparing a starting material solution. Examples of the configuration of the starting material container unit 73 include a similar configuration to the aforementioned solution for determination container unit 23.

Also, the means for preparing a starting material solution 7 is configured so as to be controllable by the control signal outputted by the aforementioned control signal output unit 62.

Next, the means for generation 8 may have such a configuration or function that properly irradiates the starting material solution with light. Examples of such a configuration include a similar configuration to the aforementioned means for generating a spin adduct/radical for determination 3.

Also, when flavin is riboflavin, the device for producing superoxide 1 according to the present embodiment can be configured so as to include, instead of the means (i), (ii), (iii), (iv), (v), and (vi), the means (viii): “a means for preparing a starting material solution 7, comprising preparing a starting material solution containing riboflavin, an electron donor, and an aqueous solvent so that a riboflavin concentration C (wol/L) is 0.1<C≦15.”

Also, in the device for producing superoxide 1 according to the present embodiment, the means for preparing a solution for determination 2 may be configured so as to serve as the means for preparing a starting material solution 7 as well, and the means for generating a spin adduct/radical for determination 3 may be configured so as to serve as the means for generation 8 as well. Alternatively, the aforementioned means may be configured separately.

Also, the present invention provides a device for evaluating the superoxide scavenging ability. The device for evaluating the superoxide scavenging ability according to the present invention is a device for evaluating the superoxide scavenging ability of a sample, comprising the following means (i), (ii), (iii), (iv), (v), (ix), (x), (xi), and (xii);

(i) a means for preparing a solution for determination, comprising preparing a solution for determination containing flavin, an electron donor, a spin trap agent, and an aqueous solvent,
(ii) a means for generating a spin adduct/radical for determination, comprising generating a superoxide spin adduct, an electron donor radical spin adduct, and/or an electron donor radical by irradiating the solution for determination with light,
(iii) a means for acquiring a spectrum for determination, comprising acquiring a spectrum by detecting the superoxide spin adduct, the electron donor radical spin adduct, and/or the electron donor radical thus generated by electron spin resonance,
(iv) a means for determining similarity, comprising determining whether or not a standard spectrum of a superoxide spin adduct and the spectrum for determination are similar,
(v) a means for acquiring a flavin concentration, comprising acquiring a concentration of flavin that is found similar by the similarity determination,
(ix) a means for preparing a solution for evaluation, comprising preparing a solution for evaluation containing flavin at the concentration as acquired above, an electron donor, a spin trap agent, a sample to be evaluated for its superoxide scavenging ability, and an aqueous solvent,
(x) a means for generating a spin adduct for evaluation, comprising generating a spin adduct by irradiating the solution for evaluation with light,
(xi) a means for acquiring a spectrum for evaluation, comprising acquiring a spectrum by detecting the spin adduct for evaluation by electron spin resonance, and
(xii) a means for comparative evaluation, comprising evaluating a superoxide scavenging ability by comparing a standard spectrum of a superoxide spin adduct with the spectrum for evaluation.

Also, the steps (i), (ii), (iii), (iv), and (v) are carried out in a similar manner to the device for producing superoxide according to the present invention.

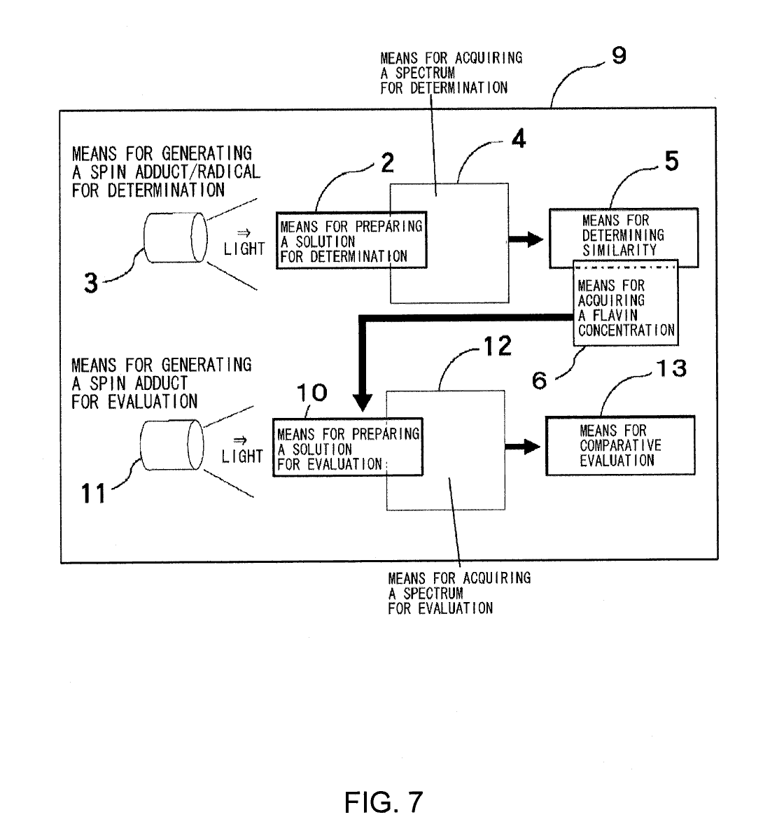

One embodiment of the device for evaluating the superoxide scavenging ability according to the present invention will be explained with reference to the drawings. FIG. 7 is a schematic diagram illustrating the basic configuration of a device for evaluating the superoxide scavenging ability 9 according to the present embodiment. As shown in FIG. 7, the device for evaluating the superoxide scavenging ability 9 is mainly composed of the means for preparing a solution for determination 2, the means for generating a spin adduct/radical for determination 3, and the means for acquiring a spectrum for determination 4, the means for determining similarity 5, the means for acquiring a flavin concentration 6, a means for preparing a solution for evaluation 10, a means for generating a spin adduct for evaluation 11, a means for acquiring a spectrum for evaluation 12, and a means for comparative evaluation 13. Also, in the configuration of the device for evaluating the superoxide scavenging ability 9, the same reference numerals are assigned to a configuration that is equivalent or corresponding to the configuration of the device for producing superoxide 1 described above to avoid redundant explanation.

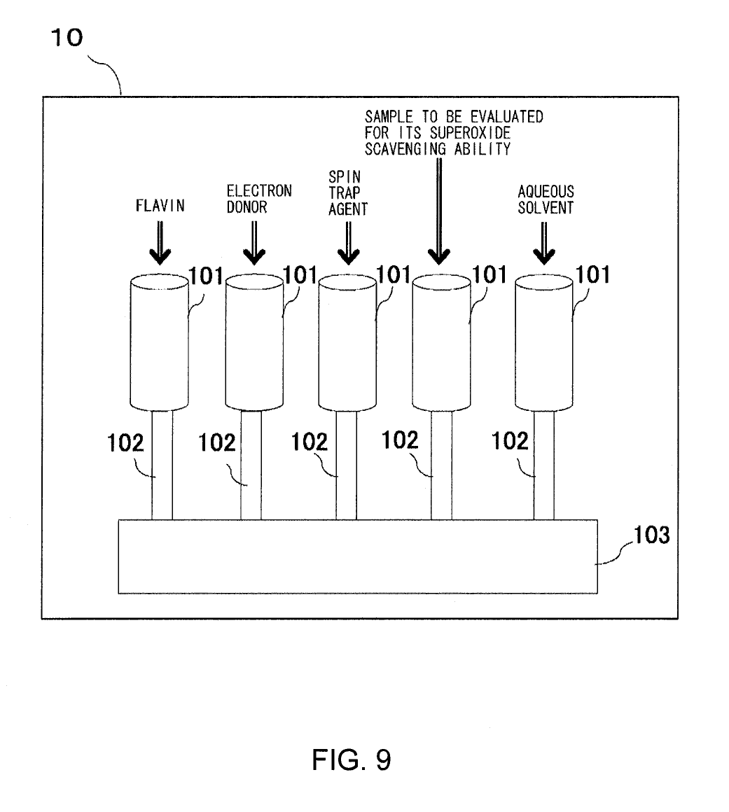

The means for preparing a solution for evaluation 10 may have such a configuration or function that properly prepares a solution for evaluation containing flavin, an electron donor, a spin trap agent, a sample to be evaluated for its superoxide scavenging ability, and an aqueous solvent. Examples of such a configuration include a configuration in which, as shown in FIG. 9, an injection pipe for evaluation 102, which is inserted through a solution for evaluation container unit 103, is formed, and a plurality of containers for evaluations with an injection volume-regulatory function 101 are disposed according to the number of substances to be injected. In this configuration, from each of the injection pipes for evaluation 102 of the containers for evaluation with an injection volume-regulatory function 101 each containing flavin, an electron donor, a spin trap agent, a sample to be evaluated for its superoxide scavenging ability, or an aqueous solvent, the adequate amounts of flavin, electron donor, spin trap agent, sample to be evaluated for its superoxide scavenging ability, and aqueous solvent are injected into the solution for evaluation container unit 103, thereby preparing a solution for evaluation. Examples of the configuration of the solution for evaluation container unit 103 include a similar configuration to the aforementioned solution for determination container unit 23. Also, the means for preparing a solution for evaluation 10 is configured so as to be controllable by the control signal outputted by the aforementioned control signal output unit 62.

Next, the means for generating a spin adduct for evaluation 11 may have such a configuration or function that properly irradiates the solution for evaluation with light. Examples of such a configuration include a similar configuration to the aforementioned means for generating a spin adduct/radical for determination 3.

Next, the means for acquiring a spectrum for evaluation 12 may have such a configuration or function that detects a spin adduct obtained by light irradiation of the solution for evaluation by electron spin resonance and obtains a spectrum of the spin adduct. Examples of such a configuration include a similar configuration to the aforementioned means for acquiring a spectrum for determination 4.

Next, the means for comparative evaluation 13 may have such a configuration or function that evaluates the superoxide scavenging ability by comparing the standard spectrum of superoxide with the spectrum for evaluation. Examples of such a configuration include a similar configuration to the aforementioned means for determining similarity 5. In this configuration, the superoxide scavenging ability can be evaluated by comparing the shape of the standard spectrum of superoxide with the shape of the spectrum for evaluation displayed on the display unit 52.

Also, in the device for evaluating the superoxide scavenging ability 9 according to the present embodiment, besides the means for determining similarity 5 and the means for acquiring a flavin concentration 6, the means for comparative evaluation 13 may also be configured by a personal computer.

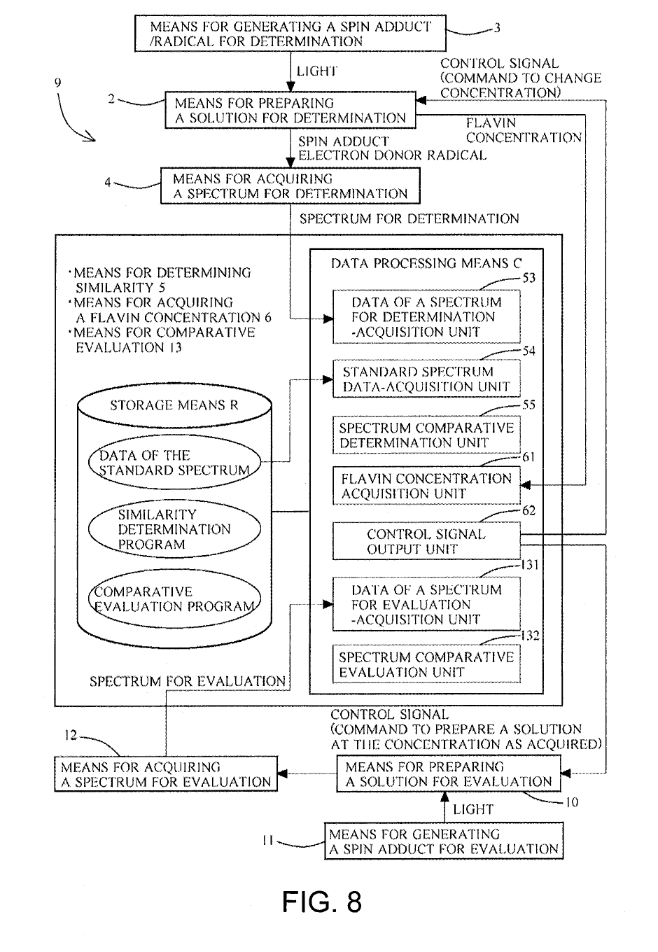

Specifically, as shown in FIG. 8, the storage means R separately stores a comparative evaluation program for executing the comparative evaluation process. Meanwhile, the data processing means C separately has, besides each component of the data processing means C in the aforementioned device for producing superoxide 1, a data of a spectrum for evaluation-acquisition unit 131 and a spectrum comparative evaluation unit 132, and performs these functions.

It is to be noted that, according to the present embodiment, when the spectrum comparative determination unit 55 determines that the spectrum for evaluation is similar to the standard spectrum of superoxide, the control signal output unit 62 sends a control signal to the means for preparing a solution for evaluation 10 to prepare a solution for evaluation based on the flavin concentration obtained by the flavin concentration acquisition unit 61.

Also, the data of a spectrum for evaluation-acquisition unit 131 acquires the spectrum for evaluation obtained by the means for acquiring a spectrum for evaluation 12 as data.

The spectrum comparative evaluation unit 132 evaluates the superoxide scavenging ability by comparing the spectrum for evaluation with the standard spectrum. Specifically, the spectrum comparative evaluation unit 132 acquires the data of the spectrum for evaluation obtained by the data of a spectrum for evaluation-acquisition unit 131 and the data of the standard spectrum obtained by the standard spectrum data-acquisition unit 54, compares both data, and based on certain evaluation criteria, evaluates the superoxide scavenging ability.

Also, when flavin is riboflavin, the device for evaluating the superoxide scavenging ability 9 according to the present embodiment can be configured so as to include, instead of the aforementioned means (i), (ii), (iii), (iv), and (viii), the means (xii): “a means for preparing a solution for evaluation 10, comprising preparing a solution for evaluation containing flavin, an electron donor, a spin trap agent, a sample to be evaluated for its superoxide scavenging ability, and aqueous solvent so that a riboflavin concentration C (μmol/L) is 0.1<C≦15.”

In the device for evaluating the superoxide scavenging ability 9 according to the present embodiment, the means for preparing a solution for determination 2 may be configured so as to serve as the means for preparing a solution for evaluation 10 as well; the means for generating a spin adduct/radical for determination 3 may be configured so as to serve as the means for generating a spin adduct for evaluation 11 as well; the means for acquiring a spectrum for determination 4 may be configured so as to serve as the means for acquiring a spectrum for evaluation 12 as well; and the means for determining similarity 5 may be configured so as to serve as the means for comparative evaluation 13 as well. Alternatively, the aforementioned means may be configured separately. Also, the device for evaluating the superoxide scavenging ability 9 according to the present embodiment may be configured so as to serve as the device for producing superoxide 1 as well.

Next, the method for producing superoxide in vivo according to the present invention is a method of applying the method for producing superoxide according to the present invention to a biological sample or in the body of a non-human animal. This method differs from the method for producing superoxide according to the present invention in the following respects: this method utilizes a body fluid of a biological sample or a non-human animal as an aqueous solvent; this method acquires the quantity of flavin (optimal amount) instead of acquiring a flavin concentration; and this method generates superoxide by irradiating, with light, the part where the flavin and the electron donor administered are present. Specifically, the method for producing superoxide in vivo comprises the following steps (A), (B), (C), (D), (E), (F), and (G);

(A) a step for administering a starting material, comprising administering arbitrary amounts of flavin, electron donor, and spin trap agent to a biological sample or into a body of a non-human animal,
(B) a step for generating a spin adduct/radical for determination, comprising generating a superoxide spin adduct, an electron donor radical spin adduct, and/or an electron donor radical by irradiating, with light, a part of the biological sample or the body of the non-human animal where the flavin and the electron donor administered are present,
(C) a step for acquiring a spectrum for determination, comprising acquiring a spectrum by detecting the superoxide spin adduct, the electron donor radical spin adduct, and/or the electron donor radical thus generated by electron spin resonance,
(D) a step for determining similarity, comprising determining whether or not a standard spectrum of a superoxide spin adduct and the spectrum for determination are similar,
(E) a step for acquiring an optimal amount of flavin, comprising acquiring the optimal amount of flavin that is found similar by the similarity determination,
(F) a step for administering an optimal starting material, comprising administering adequate amounts of flavin obtained as above and electron donor to the biological sample or into the body of the non-human animal, and
(G) a step for generating superoxide, comprising irradiating, with light, a part of the biological sample or the body of the non-human animal where the flavin and the electron donor administered are present.

As the biological sample in the present invention, a biological sample isolated and collected from animals including humans, particularly mammals, can be used. For example, a biological sample isolated and collected from the affected and aged mammals and experimental animals can be used. As to its form, for example, a solid sample such as a tissue section and a cell are desirable. Also, in the present invention, the non-human animal includes animals other than humans, and examples thereof include mammals such as cows, monkeys (primates excluding humans), pigs, goats, dogs, cats, guinea pigs, rabbits, hamsters, rats, and mice, poultry such as chickens and turkeys, reptiles, amphibians, and fishes.

In the present invention, a method for administering a substance such as flavin and an electron donor to a biological sample or into the body of a non-human animal may be performed according to a routine procedure. Examples of a method for administering to a biological sample include a membrane fusion method involving the fusion of liposomes entrapping flavin and an electron donor, and a microinjection method, and examples of a method for administering to a non-human animal include an oral administration method and a subcutaneous injection method.

Also, the body fluid encompasses not only an extracellular fluid but also an intracellular fluid, and examples of the extracellular fluid include blood and lymph, and moreover, a tissue fluid such as an interstitial fluid, intercellular fluid, and interstitial fluid, celomic fluid such as chorionic cavity fluid, cerebrospinal fluid, synovial fluid, and aqueous humor, digestive juices, urine, semen, vaginal fluid, amniotic fluid, and milk.

Next, the method for evaluating the superoxide scavenging ability in vivo according to the present invention is a method of applying the method for evaluating the superoxide scavenging ability according to the present invention to a biological sample or in the body of a non-human animal. This method differs from the method for producing superoxide according to the present invention in the following respects: this method utilizes a body fluid of a biological sample or a non-human animal as an aqueous solvent, this method acquires the quantity of flavin (optimal amount) instead of acquiring a flavin concentration, and this method generates superoxide or a spin adduct by irradiating, with light, a specimen for evaluation containing the flavin and electron donor administered or the flavin, electron donor, spin trap agent, and sample to be evaluated for its superoxide scavenging ability administered. Specifically, the method for evaluating the superoxide scavenging ability in vivo comprises the following steps (A), (B), (C), (D), (E), (F), and (G);

(A) a step for administering a starting material, comprising administering arbitrary amounts of flavin, an electron donor, and a spin trap agent to a biological sample or into a body of a non-human animal,
(B) a step for generating a spin adduct/radical for determination, comprising generating a superoxide spin adduct, an electron donor radical spin adduct, and/or an electron donor radical by irradiating, with light, a part of the biological sample or the body of the non-human animal where the flavin and the electron donor administered are present,
(C) a step for acquiring a spectrum for determination, comprising acquiring a spectrum by detecting the superoxide spin adduct, the electron donor radical spin adduct, and/or the electron donor radical thus generated by electron spin resonance,
(D) a step for determining similarity, comprising determining whether or not a standard spectrum of a superoxide spin adduct and the spectrum for determination are similar,
(E) a step for acquiring an optimal amount of flavin, comprising acquiring an optimal amount of flavin that is found similar by the similarity determination,
(H) a step for administering a specimen for evaluation, comprising administering a specimen for evaluation containing the optimal amount of flavin acquired above, an electron donor, a spin trap agent, and a sample to be evaluated for its superoxide scavenging ability to the biological sample or into a body of a non-human animal,
(I) a step for generating a spin adduct in vivo, comprising generating a spin adduct by irradiating, with light, the administered specimen for evaluation in the biological sample or the body of the non-human animal,
(J) a step for acquiring a spectrum in vivo, comprising acquiring a spectrum by detecting the spin adduct by electron spin resonance, and
(K) an in vivo comparative evaluation step, comprising evaluating a superoxide scavenging ability by comparing a standard spectrum of a superoxide spin adduct with the spectrum acquired as above.

Step (H): In the step for administering a specimen for evaluation, when administering a specimen for evaluation, it may be prepared from flavin, an electron donor, a spin trap agent, and a sample to be evaluated for its superoxide scavenging ability prior to administration. Alternatively, flavin, an electron donor, a spin trap agent, and a sample to be evaluated for its superoxide scavenging ability may be each directly administered to a biological sample or into the body of a non-human animal so that a specimen for evaluation is prepared within the biological sample or the body of the non-human animal.

Also, the specimen for evaluation may contain other substances such as a buffer, a solvent, and an excipient in addition to flavin, an electron donor, a spin trap agent, and a sample to be evaluated for its superoxide scavenging ability so long as its characteristics are not impaired.

Hereinbelow, the method for producing superoxide, the method for evaluating the superoxide scavenging ability, the device for producing superoxide, and the device for evaluating the superoxide scavenging ability according to the present invention will be explained based on Examples. It should be noted that the technical scope of the present invention is not limited to the features demonstrated by the following Examples.

### EXAMPLES

### Example 1

### Measurement of a Radical Generated by Light Irradiation of an Aqueous Solution Containing Riboflavin, EDTA, and CYPMPO by Electron Spin Resonance

An aqueous solution containing riboflavin as a redox reaction catalyst, EDTA as an electron donor, and CYPMPO as a spin trap agent was prepared, with was irradiated with light to generate a radical. The radical thus generated was identified and quantified by Electron Spin Resonance (ESR).

(1) Preparation of an Aqueous Solution

Into a 50 mmol/L phosphate buffer with pH 7.4, riboflavin, EDTA, and CYPMPO (Radical Research Inc.) were each added at 1 μmol/L, 5 mmol/L, and 10 mmol/L, respectively, to prepare an aqueous solution (SOD-free aqueous solution). To the aqueous solution thus prepared, superoxide dismutase (SOD) (Sigma), which is an enzyme that specifically scavenges superoxide, was added at 10 U/mL to separately prepare an aqueous solution with added SOD.

(2) Measurement by ESR

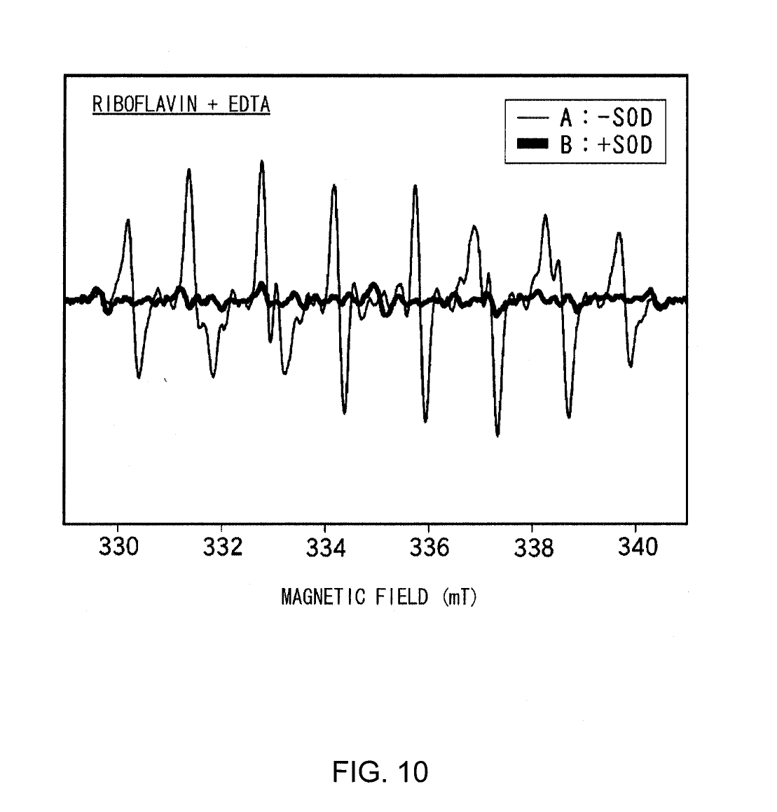

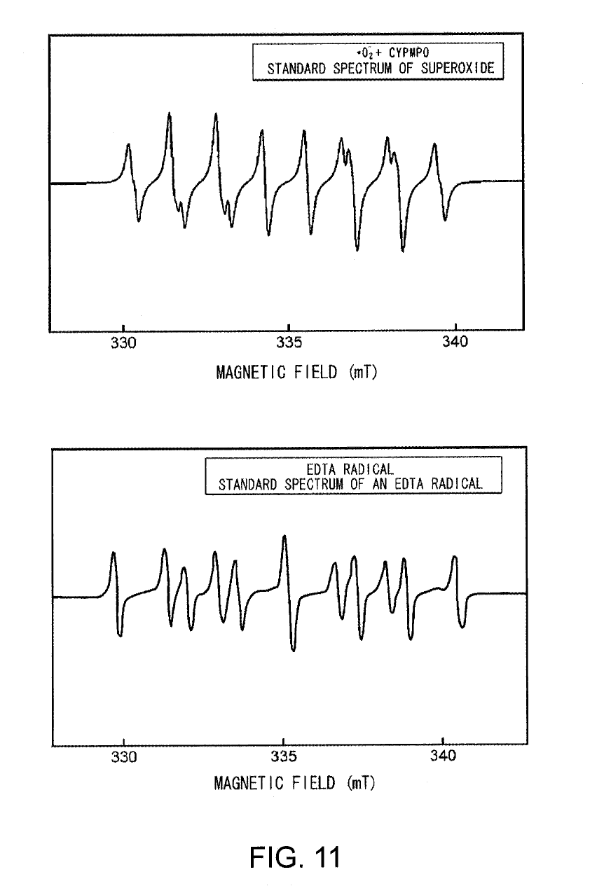

The aqueous solutions prepared in the present Example (1) (aqueous solutions with or without SOD) were each introduced into the sample tube of the electron spin resonance device JES-RE1X (JEOL Ltd.). Using a xenon lamp, the sample tube was irradiated with visible light of 1500 lux for 30 seconds. Subsequently, a measurement was made by ESR under the following measurement conditions to obtain a spectrum. The spectrum of the SOD-free aqueous solution was obtained as Spectrum A, and the spectrum of the aqueous solution with added SOD was obtained as Spectrum B. The results thus obtained are shown in FIG. 10. Also, a spectrum of a spin adduct composed of superoxide and CYPMPO obtained by computer simulation (the standard spectrum of superoxide; M. Kamibayashi et al., Free Radical Research, Vol. 40, No. 11, pages 1166 to 1172, 2006) and a spectrum of EDTA that is transformed into a radical (EDTA radical) obtained by computer simulation (the standard spectrum of an EDTA radical) are shown in FIG. 11.

Conditions of ESR measurement

Power output: 6 mW

Magnetic field sweep width: ±7.5 mT

Measurement time: 2 minutes

Modulation width: 0.1 mT

Time constant: 0.1 second

As shown in FIGS. 10 and 11, it was confirmed that the shape of Spectrum A in FIG. 10 and the shape of the standard spectrum of superoxide in the top diagram of FIG. 11 were almost the same, and the signal intensity of the standard spectrum of superoxide was hardly different from the signal intensity of Spectrum A. It was further confirmed that the shape of Spectrum B in FIG. 10 and the shape of the standard spectrum of an EDTA radical in the bottom diagram of FIG. 11 were almost the same. Further, as shown in FIG. 10, it was confirmed that the signal intensity of Spectrum B was smaller than the signal intensity of Spectrum A, and the peaks observed in Spectrum A were absent in Spectrum B.

From these results, it was shown that the peaks observed in Spectrum A were derived from a superoxide spin adduct, indicating that a large amount of superoxide was generated in the SOD-free aqueous solution. Also, it was shown that the peaks observed in Spectrum B were derived from the EDTA radical, and taking also into consideration that the peaks observed in Spectrum A were absent in Spectrum B, it was shown that the aqueous solution with added SOD generated a small amount of EDTA radicals but not superoxide.

From these findings, it was revealed that the aqueous solution according to the present Example made it possible to generate two kinds of radicals, namely superoxide and an electron donor radical (interfering radical or TH. radical), and of these radicals, selectively generate superoxide. It was also revealed that the addition of a substance having a superoxide scavenging ability to this aqueous solution inhibited the generation of superoxide.

### Example 2

### Study on a Redox Reaction Catalyst and an Electron Donor

A redox reaction catalyst and an electron donor that are suitable for generating superoxide were studied by generating a radical by light irradiation using various redox reaction catalysts or electron donors, and identifying and quantifying the radical thus generated by ESR.

(1) Generation of Superoxide by Using Tetramethylethylenediamine (TMD) as an Electron Donor

Using tetramethylethylenediamine (TMD) instead of EDTA employed in Example 1 as an electron donor, an aqueous solution was prepared. It was irradiated with light to generate a radical, which was identified and quantified by ESR.

Into a 50 mmol/L phosphate buffer with pH 7.4, riboflavin, TMD, and CYPMPO (Radical Research Inc.) were each added at 10 μmol/L, 10 mmol/L, and 10 mmol/L, respectively, to prepare an aqueous solution.

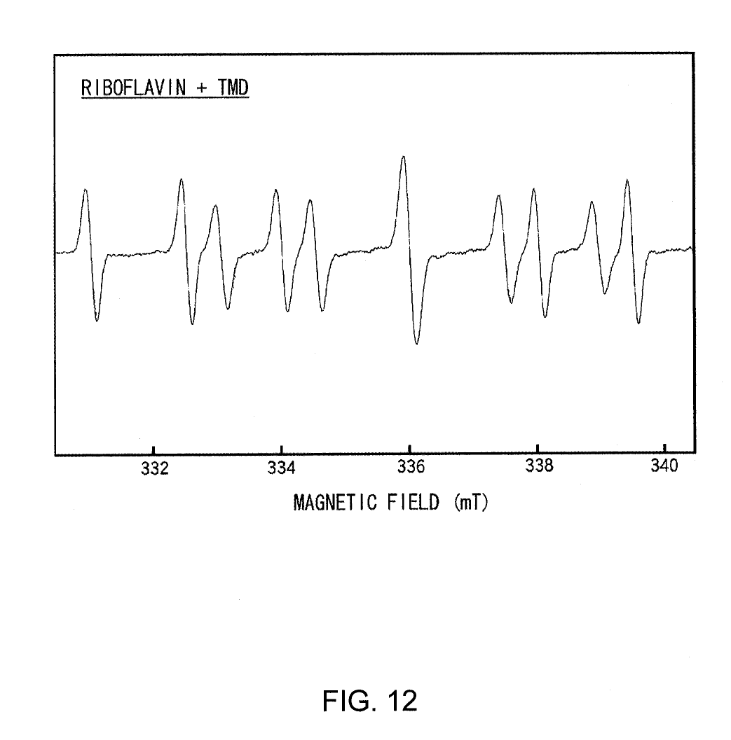

Following a similar operation to Example 1 (2), this aqueous solution was measured by ESR to obtain a spectrum. The spectrum thus obtained is shown in FIG. 12.

As shown in the top diagram of FIG. 11 and FIG. 12, it was confirmed that the shape of the standard spectrum of superoxide in the top diagram of FIG. 11 was different from the spectral shape of FIG. 12.

(2) Generation of Superoxide by Using Methionine as an Electron Donor

Using methionine as an electron donor instead of EDTA employed in Example 1, an aqueous solution was prepared. It was irradiated with light to generate a radical, which was identified and quantified by ESR.

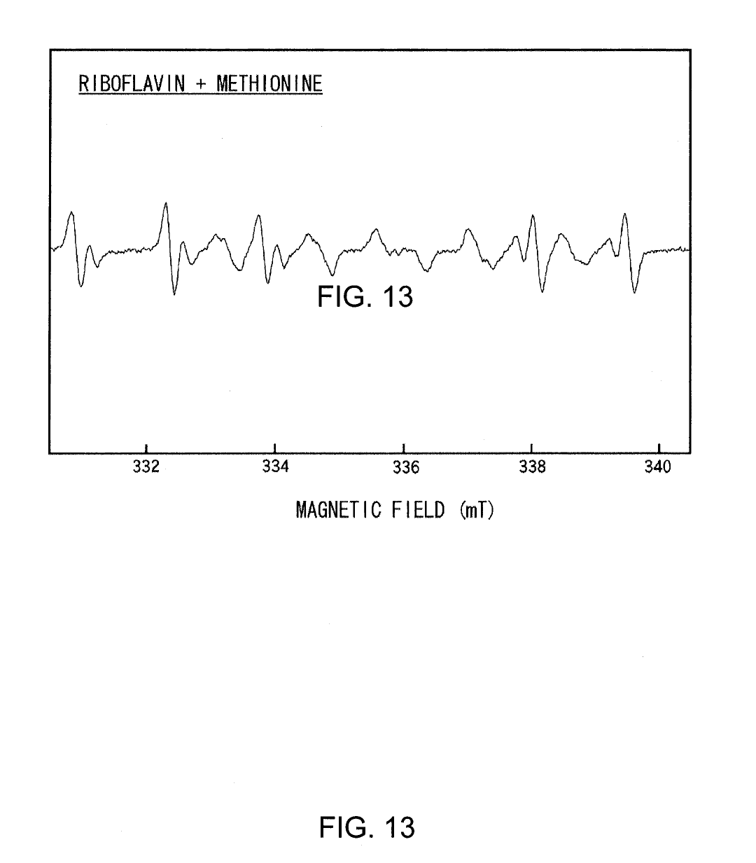

Replacing TMD by methionine, an aqueous solution was prepared by a similar operation to the present Example (1) and measured by ESR to obtain a spectrum. The spectrum thus obtained is shown in FIG. 13.

As shown in the top diagram of FIG. 11 and FIG. 13, it was confirmed that the shape of the standard spectrum of superoxide in the top diagram of FIG. 11 was different from the spectral shape of FIG. 13.

(3) Generation of Superoxide by Using Flavin Mononucleotide (FMN) as a Redox Reaction Catalyst

Using flavin mononucleotide (FMN) as a redox reaction catalyst instead of riboflavin employed in Example 1, an aqueous solution was prepared. It was irradiated with light to generate a radical, which was identified and quantified by ESR.

Into a 50 mmol/L phosphate buffer with pH 7.4, FMN, EDTA, and CYPMPO (Radical Research Inc.) were each added at 5 μmol/L, 5 mmol/L, and 10 mmol/L, respectively, to prepare an aqueous solution.

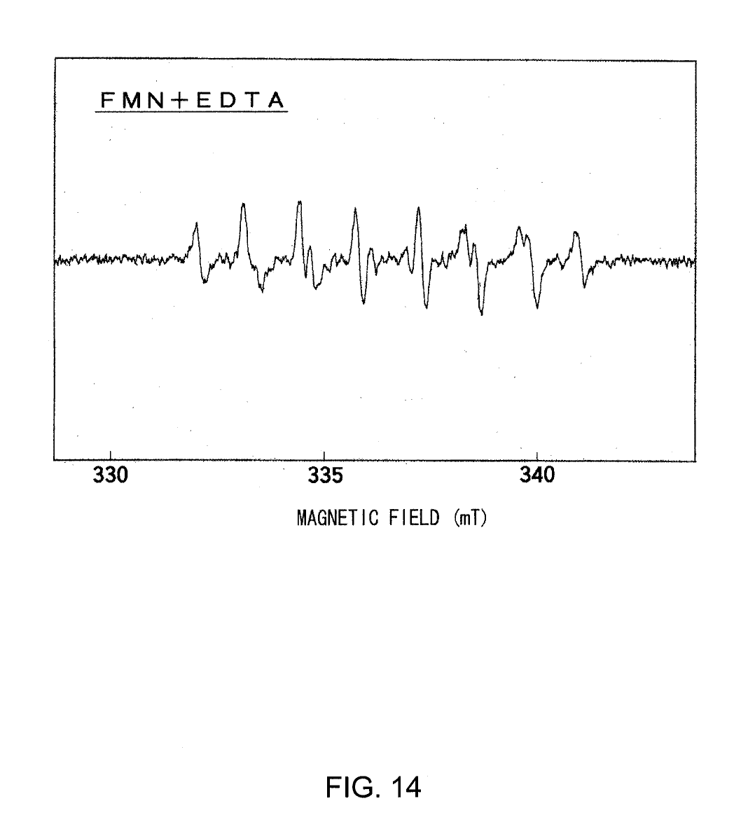

Following a similar operation to Example 1 (2), this aqueous solution was measured by ESR to obtain a spectrum. The spectrum thus obtained is shown in FIG. 14.

As shown in FIGS. 11 and 14, it was confirmed that the shape of the standard spectrum of superoxide in the top diagram of FIG. 11 and the spectral shape of FIG. 14 were in a similarity relationship, while the shape of the standard spectrum of the EDTA radical in the bottom diagram of FIG. 11 was different from the spectral shape of FIG. 14.

(4) Generation of Superoxide by Using Flavin Mononucleotide (FMN) as a Redox Reaction Catalyst and Tetramethylethylenediamine (TMD) as an Electron Donor

Using flavin mononucleotide (FMN) as a redox reaction catalyst and tetramethylethylenediamine (TMD) as an electron donor instead of riboflavin and EDTA employed in Example 1, respectively, an aqueous solution was prepared. It was irradiated with light to generate a radical, which was identified and quantified by ESR.

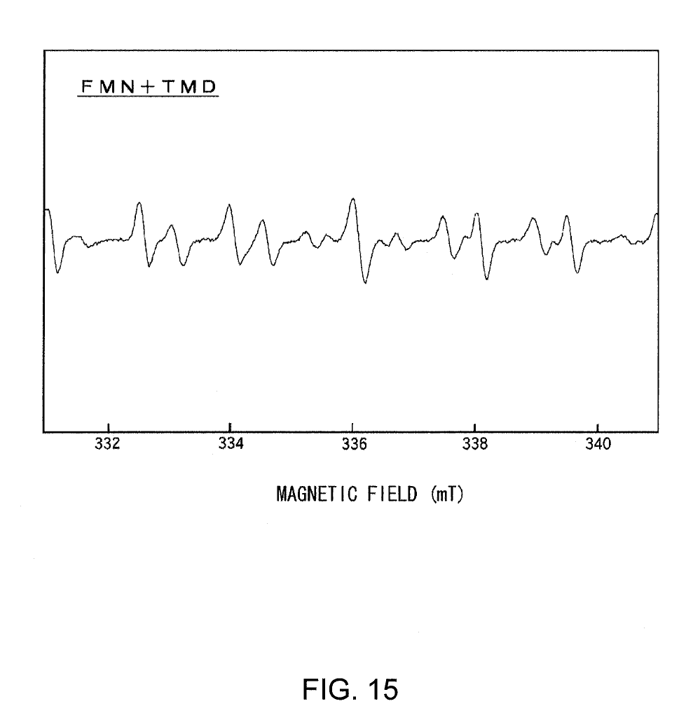

Replacing riboflavin by FMN, an aqueous solution was prepared by a similar operation to the present Example (1) and measured by ESR to obtain a spectrum. The spectrum thus obtained is shown in FIG. 15.

As shown in the top diagram of FIG. 11 and FIG. 15, it was confirmed that the shape of the standard spectrum of superoxide in the top diagram of FIG. 11 was different from the spectral shape of FIG. 15.

(5) Generation of Superoxide by Using Fluorescein as a Redox Reaction Catalyst and Methionine as an Electron Donor

Using fluorescein as a redox reaction catalyst and methionine as an electron donor instead of riboflavin and EDTA employed in Example 1, respectively, an aqueous solution was prepared. It was irradiated with light to generate a radical, which was identified and quantified by ESR.

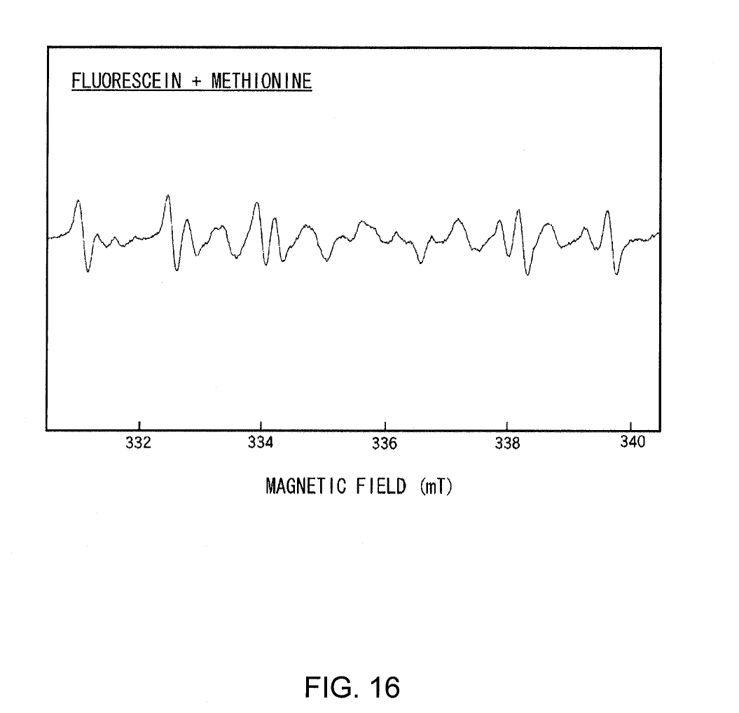

Replacing riboflavin by fluorescein and TMD by methionine, an aqueous solution was prepared by a similar operation to the present Example 1 and measured by ESR to obtain a spectrum. The spectrum thus obtained is shown in FIG. 16.

As shown in the top diagram of FIG. 11 and FIG. 16, it was confirmed that the shape of the standard spectrum of superoxide in the top diagram of FIG. 11 was different from the spectral shape of FIG. 16.

From the results of the present Examples (1) to (5), it was revealed that compared to any of the cases in which riboflavin was used as a redox reaction catalyst and TMD was used as an electron donor; riboflavin was used as a redox reaction catalyst and methionine was used as an electron donor; FMN was used as a redox reaction catalyst and TMD was used as an electron donor; and fluorescein was used as a redox reaction catalyst and methionine was used as an electron donor, the case in which riboflavin or FMN was used as a redox reaction catalyst and EDTA was used as an electron donor could produce a radical containing superoxide at a high purity, while inhibiting the generation of an electron donor radical (interfering radical or TH. radical).

### Example 3

### Study on the Relationship Among the Riboflavin Concentration, the Amount of Superoxide Generated, and the Purity of Superoxide

The changes in the amounts of superoxide and an electron donor radical (interfering radical or TH. radical) generated were confirmed by varying the riboflavin concentration of an aqueous solution.

Aqueous solutions prepared in Example 1 (1) (an aqueous solution with added SOD or an SOD-free aqueous solution) were prepared so that each aqueous solution had a riboflavin concentration of 0.1 μmol/L, 0.5 μmol/L, 1 μmol/L, 2.5 μmol/L, 5 μmol/L, 10 μmol/L, 15 μmol/L, 25 μmol/L, or 50 μmol/L.

Following a similar operation to Example 1 (2), each of these aqueous solutions was measured by ESR to obtain a spectrum.

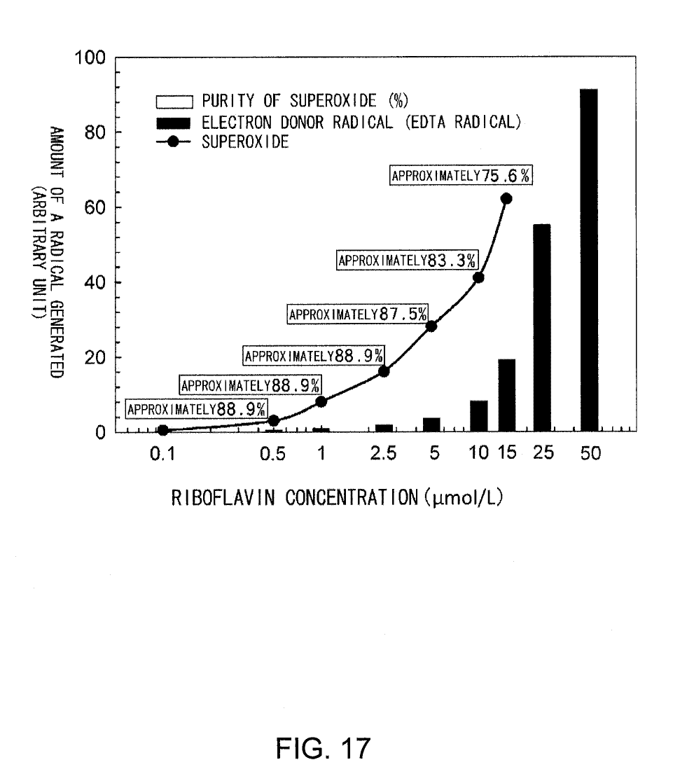

Based on the spectra thus obtained, a radical generated in each aqueous solution was identified and the amount of radical generated was quantified. That is, based on the spectrum of an aqueous solution with added SOD, the amount of EDTA radical (interfering radical) generated was quantified, and based on the spectrum of an SOD-free aqueous solution, the amount of superoxide generated was quantified. It is to be noted that quantification of the amount of superoxide was conducted when the subject spectrum was determined to have a unique spectral shape of superoxide based on the shape of the standard spectrum of superoxide (top diagram of FIG. 11). Also, based on the results of quantification, the purity of superoxide in the radical generated in the aqueous solution having each riboflavin concentration was calculated by the following formula 4. The results thus obtained are shown in FIG. 17.

Purity of superoxide (%)=[amount of superoxide generated/{amount of superoxide generated+amount of an EDTA radical (interfering radical) generated)}]×100 (Formula 4)

As shown in FIG. 17, it was confirmed that neither superoxide nor EDTA radical (interfering radical) was generated in an aqueous solution having a riboflavin concentration of 0.1 μmol/L. Also, it was confirmed that in the aqueous solutions having riboflavin concentrations of 0.5 μmol/L, 1 μmol/L, and 2.5 μmol/L, superoxide was generated, while almost no EDTA radical (interfering radical) was produced, and the purity of superoxide was approximately 88.9%. It was also confirmed that in the aqueous solutions having riboflavin concentrations of 5 μmol/L, 10 μmol/L, and 15 μmol/L, a large amount of superoxide was generated, while almost no EDTA radical (interfering radical) was generated, and the purity of superoxide was 87.5%, approximately 83.3%, and approximately 76.5%, respectively. Also, the signal derived from an EDTA radical (interfering radical) was so intense in the aqueous solutions having riboflavin concentrations of 25 mmol/L and 50 μmol/L that quantification of the amount of superoxide generated and calculation of the purity of superoxide were not performed.

From the above results, it was revealed that almost no electron donor radical (interfering radical or TH. radical) was generated, while a large amount of superoxide was generated in an aqueous solution having a riboflavin concentration C (μmol/L) of 0.1<C<25, particularly in an aqueous solution having a riboflavin concentration C (μmol/L) of 0.5≦C≦15.

### Example 4

### Confirmation of the Relationship Between Light Irradiation Time and the Amount of Superoxide Generated

The relationship between the time from the initiation of light irradiation to the generation of superoxide, the time from discontinuation of light irradiation to discontinuation of generation of superoxide, and the light irradiation time and the amount of superoxide generated was confirmed.

(1) Preparation of an Aqueous Solution

Into a 50 mmol/L phosphate buffer with pH 7.4, riboflavin, EDTA, and CYPMPO (Radical Research Inc.) were each added at 1 μmol/L, 3 mmol/L, and 10 mmol/L, respectively, to prepare an aqueous solution. The aqueous solution thus prepared was divided into 16 samples, which were each provided as samples 1 to 16.

(2) Measurement by ESR

The aqueous solutions prepared in the present Example (1) were each introduced into the sample tube of the electron spin resonance device JES-RE1X (JEOL Ltd.), followed by irradiation with visible light for various irradiation times. The samples were then measured by ESR to obtain spectra. The irradiation time of visible light in each sample is shown below. Measurement with ESR was performed by fixing the observation magnetic field of ESR at 335.7 mT (the same magnetic field as that at which the superoxide-derived peak was confirmed in Example 1). Other conditions of light irradiation and conditions of measurement by ESR were similar to those employed in Example 1 (2).

Time of irradiation of visible light

Sample 1: 30 seconds before initiation of irradiation (−30)
Sample 2: 15 seconds before initiation of irradiation (−15)
Sample 3: 0 second before initiation of irradiation (0)
Sample 4: Irradiating for 5 seconds (5)
Sample 5: Irradiating for 10 seconds (10)
Sample 6: Irradiating for 15 seconds (15)
Sample 7: Irradiating for 20 seconds (20)
Sample 8: Irradiating for 30 seconds (30)
Sample 9: Irradiating for 45 seconds (45)
Sample 10: Irradiating for 60 seconds (60)
Sample 11: Irradiating for 60 seconds, and thereafter, 5 seconds after discontinuation of irradiation (+5)
Sample 12: Irradiating for 60 seconds, and thereafter, 10 seconds after discontinuation of irradiation (+10)
Sample 13: Irradiating for 60 seconds, and thereafter, 20 seconds after discontinuation of irradiation (+20)
Sample 14: Irradiating for 60 seconds, and thereafter, 30 seconds after discontinuation of irradiation (+30)
Sample 15: Irradiating for 60 seconds, and thereafter, 60 seconds after discontinuation of irradiation (+60)
Sample 16: Irradiating for 60 seconds, and thereafter, 120 seconds after discontinuation of irradiation (+120)

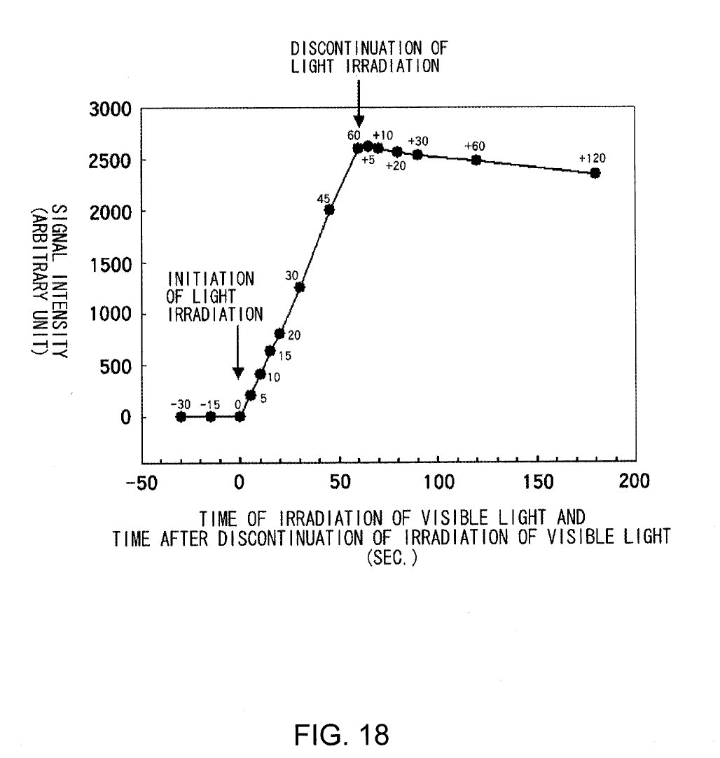

The results were graphed with the signal intensity of the spectrum thus obtained on the vertical axis and the time of irradiation of visible light on the horizontal axis. The results thus obtained are shown in FIG. 18.

As shown in FIG. 18, a signal was confirmed soon after the initiation of light irradiation, and the signal intensity was confirmed to be strengthened in proportion to the time of irradiation of visible light. In other words, the amount of a superoxide spin adduct produced increases in proportion to the light irradiation time. Also, it was confirmed that the signal intensity tapered off gradually in proportion to time with discontinuation of light irradiation. That is, it shows that the amount of a superoxide spin adduct produced gradually decreases in proportion to time.

From the above results, it was revealed that generation of superoxide occurred with initiation of light irradiation and discontinued with discontinuation of light irradiation. Also, it was confirmed that superoxide was continuously and stably generated while light irradiation is continued.

### Comparative Example 1

### Comparison of the Purity of Superoxide in a Radical Generated by Light Irradiation of Riboflavin and the Purity of Superoxide in a Radical Generated by Xanthine Oxidase

The purity of superoxide in a radical generated by light irradiation of riboflavin was studied by comparing the degree of inhibition of the generation of radicals by

SOD between generation of superoxide by light irradiation of riboflavin and generation of superoxide by xanthine oxidase.

(1) Quantification of the Amount of a Radical Generated by Light Irradiation of Riboflavin

Aqueous solutions with added SOD in Example 1 (1) were prepared so that each solution had a SOD concentration of 0.5 U/mL, 1 U/mL, or 1.5 U/mL, and separately, a SOD-free aqueous solution was prepared.

Following a similar operation to Example 1 (2), each of the aqueous solutions thus prepared was measured by ESR to obtain a spectrum. Based on the spectrum thus obtained, the amount of a radical generated was quantified.

(2) Quantification of the Amount of a Radical Generated by Xanthine Oxidase

Into a 50 mmol/L phosphate buffer with pH 7.4, hypoxanthine, CYPMPO (Radical Research Inc.), and diethylenetriaminopentaacetic acid (DETAPAC) were each added at 0.39 mmol/L, 10 mmol/L, and 0.1 mmol/L, respectively, to prepare an aqueous solution (SOD-free aqueous solution). Further, to this aqueous solution, SOD (Sigma) was added at a concentration of 0.5 U/mL, 1 U/mL, and 1.5 U/mL to separately prepare aqueous solutions with added SOD.

To each of the SOD-free aqueous solution and aqueous solutions with added SOD thus prepared, xanthine oxidase was added at 0.2 U/mL. Following a similar operation to Example 1 (2), each of the aqueous solutions was measured by ESR to obtain a spectrum. Subsequently, based on the spectrum thus obtained, the amount of a radical generated was quantified. Measurement by ESR was performed 60 seconds after the addition of xanthine oxidase.

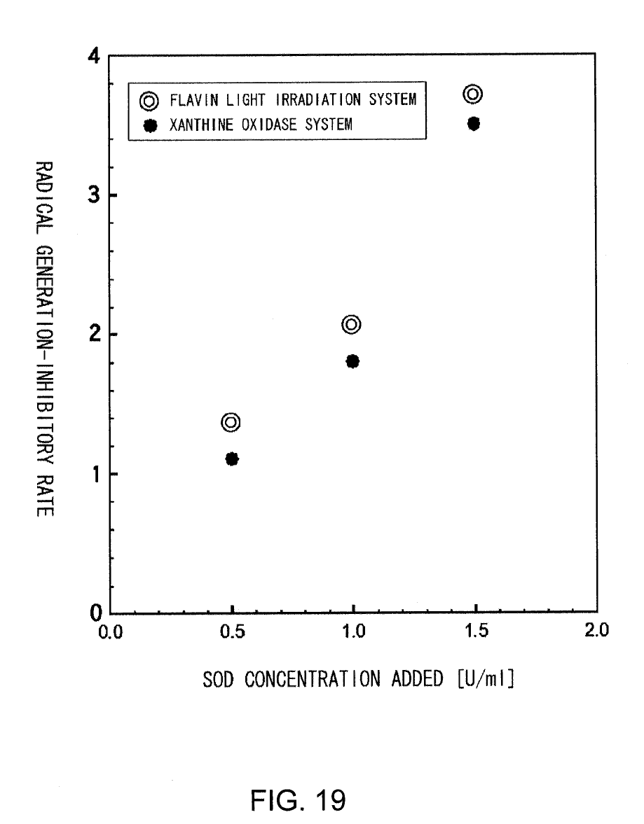

Based on the quantification results of the amount of a radical generated in the present Examples (1) and (2), the radical generation-inhibitory rate by SOD was calculated by the following formula 5. The results thus obtained are shown in FIG. 19.

Radical generation-inhibitory rate by SOD=(S₀−S)/S (Formula 5)

S₀: Amount of a radical generated when no SOD is added
S: Amount of a radical generated when SOD is added

It should be noted that because SOD does not act on an electron donor radical (interfering radical or TH. radical) but degrades only superoxide, the radical generation-inhibitory rate by SOD indicates the purity of superoxide. That is, the higher the purity of superoxide in a radical generated, the higher the radical generation-inhibitory rate by SOD.

As shown in FIG. 19, it was confirmed that, comparing generation of superoxide by light irradiation of riboflavin and generation of superoxide by xanthine oxidase, approximately the same values of radical generation-inhibitory rate were observed, irrespective of the SOD concentration added.

Considering that the purity of superoxide in the radical generated by xanthine oxidase is known to be high, the above results revealed that a radical containing superoxide at a high purity was obtained by generating a radical by light irradiation of riboflavin under the reaction conditions specified in the present Examples.

### REFERENCE SIGNS LIST

1 Device for producing superoxide
2 Means for preparing a solution for determination
3 Means for generating a spin adduct/radical for determination
4 Means for acquiring a spectrum
5 Means for determining similarity
6 Means for acquiring a flavin concentration
7 Means for preparing a starting material solution
8 Means for generation
9 Device for evaluating the superoxide scavenging ability
10 Means for preparing a solution for evaluation
11 Means for generating a spin adduct for evaluation
12 Means for acquiring a spectrum for evaluation
13 Means for comparative evaluation
21 Container for determination having an injection volume-regulatory function
22 Injection pipe for determination
23 Solution for determination container unit
41 Electromagnet
42 Microwave oscillator
43 Crystalline diode detector
44 Amplifier
45 Recorder
51 Input unit
52 Display unit
53 Data of a spectrum for determination-acquisition unit
54 Standard spectrum data-acquisition unit
55 Spectrum comparative determination unit
61 Flavin concentration acquisition unit
62 Control signal output unit
71 Starting material container having an injection volume-regulatory function
72 Starting material injection pipe
73 Starting material container unit
101 Container for evaluation having an injection volume-regulatory function
102 Injection pipe for evaluation
103 Solution for evaluation container unit
131 Data of a spectrum for evaluation-acquisition unit
132 Spectrum comparative evaluation unit
C Data processing means
R Storage means

1. A method for selectively producing superoxide, comprising the following steps of (a), (b), (c), (d), (e), (f), and (g);
(a) a step for preparing a solution for determination, comprising preparing a solution for determination containing flavin, an electron donor, a spin trap agent, and an aqueous solvent,
(b) a step for generating a spin adduct/radical for determination, comprising generating a superoxide spin adduct, an electron donor radical spin adduct, and/or an electron donor radical by irradiating the solution for determination with light,
(c) a step for acquiring a spectrum for determination, comprising acquiring a spectrum by detecting the superoxide spin adduct, the electron donor radical spin adduct, and/or the electron donor radical thus generated by electron spin resonance,
(d) a step for determining similarity, comprising determining whether or not a standard spectrum of a superoxide spin adduct and the spectrum for determination are similar,
(e) a step for acquiring a flavin concentration, comprising acquiring a flavin concentration of a solution for determination from which the spectrum for determination that is considered to be similar by the similarity determination is acquired,
(f) a step for preparing a starting material solution, comprising preparing a starting material solution containing flavin at the concentration as acquired above, an electron donor, and an aqueous solvent, and
(g) a step for generation, comprising generating superoxide by irradiating the starting material solution with light.

2. (canceled)

3. The method for selectively producing superoxide according to claim 1, wherein the step for acquiring a flavin concentration comprises acquiring a concentration of flavin that is found similar by the similarity determination so that a purity of the superoxide in a radical to be generated is 75.6 to 100%.

4. The method for selectively producing superoxide according to claim 1, wherein the electron donor is EDTA.

5. The method for selectively producing superoxide according to claim 1, wherein the spin trap agent is CYPMPO.

6. The method for selectively producing superoxide according to claim 1, wherein the aqueous solvent is a phosphate buffer.

7. A method for evaluating a superoxide scavenging ability of a sample, comprising the following steps (a), (b), (c), (d), (e), (i), (j), (k), and (l);
(a) a step for preparing a solution for determination, comprising preparing a solution for determination containing flavin, an electron donor, a spin trap agent, and an aqueous solvent,
(b) a step for generating a spin adduct/radical for determination, comprising generating a superoxide spin adduct, an electron donor radical spin adduct, and/or an electron donor radical by irradiating the solution for determination with light,
(c) a step for acquiring a spectrum for determination, comprising acquiring a spectrum by detecting the superoxide spin adduct, the electron donor radical spin adduct, and/or the electron donor radical thus generated by electron spin resonance,
(d) a step for determining similarity, comprising determining whether or not a standard spectrum of a superoxide spin adduct and the spectrum for determination are similar,
(e) a step for acquiring a flavin concentration, comprising acquiring a flavin concentration of a solution for determination from which the spectrum for determination that is considered to be similar by the similarity determination is acquired,
(i) a step for preparing a solution for evaluation, comprising preparing a solution for evaluation containing flavin at the concentration as acquired above, an electron donor, a spin trap agent, a sample to be evaluated for its superoxide scavenging ability, and an aqueous solvent,
(j) a step for generating a spin adduct for evaluation, comprising generating a spin adduct by irradiating the solution for evaluation with light,
(k) a step for acquiring a spectrum for evaluation, comprising acquiring a spectrum by detecting the spin adduct for evaluation by electron spin resonance, and
(l) a step for comparative evaluation, comprising evaluating a superoxide scavenging ability by comparing a standard spectrum of a superoxide spin adduct with the spectrum for evaluation.

8. The method according to claim 7, wherein the method comprises the following step (m) instead of the steps (a), (b), (c), (d), (e), and (i), when flavin is riboflavin;
(m) a step for preparing a solution for evaluation, comprising preparing a solution for evaluation containing riboflavin, an electron donor, a spin trap agent, a sample to be evaluated for its superoxide scavenging ability, and an aqueous solvent so that a riboflavin concentration C (μmol/L) is 0.1<C≦15.

9. The method according to claim 7, wherein the step for acquiring a flavin concentration comprises acquiring a concentration of flavin that is found similar by the similarity determination so that a purity of the superoxide in a radical to be generated is 75.6 to 100%.

10. The method according to claim 7, wherein the electron donor is EDTA.

11. The method according to claim 7, wherein the spin trap agent is CYPMPO.

12. The method according to claim 7, wherein the aqueous solvent is a phosphate buffer.

13. A device for selectively producing superoxide, comprising the following means (i), (ii), (iii), (iv), (v), (vi), and (vii);
(i) a means for preparing a solution for determination, comprising preparing a solution for determination containing flavin, an electron donor, a spin trap agent, and an aqueous solvent,
(ii) a means for generating a spin adduct/radical for determination, comprising generating a superoxide spin adduct, an electron donor radical spin adduct, and/or an electron donor radical by irradiating the solution for determination with light,
(iii) a means for acquiring a spectrum for determination, comprising acquiring a spectrum by detecting the superoxide spin adduct, the electron donor radical spin adduct, and/or the electron donor radical thus generated by electron spin resonance,
(iv) a means for determining similarity, comprising determining whether or not a standard spectrum of a superoxide spin adduct and the spectrum for determination are similar,
(v) a means for acquiring a flavin concentration, comprising acquiring a flavin concentration of a solution for determination from which the spectrum for determination that is considered to be similar by the similarity determination is acquired,
(vi) a means for preparing a starting material solution, comprising preparing a starting material solution containing flavin at the concentration as acquired above, an electron donor, and an aqueous solvent, and
(vii) a means for generation, comprising generating superoxide by irradiating the starting material solution with light.

14. (canceled)

15. The device for selectively producing superoxide according to claim 13, wherein the means for acquiring a flavin concentration comprises acquiring a concentration of flavin that is found similar by the similarity determination so that a purity of the superoxide in a radical to be generated is 75.6 to 100%.

16. The device for selectively producing superoxide according to claim 13, wherein the electron donor is EDTA.

17. The device for selectively producing superoxide according to claim 13, wherein the spin trap agent is CYPMPO.

18. The device for selectively producing superoxide according to claim 13, wherein the aqueous solvent is a phosphate buffer.

19. A device for evaluating a superoxide scavenging ability of a sample, comprising the following means (i), (ii), (iii), (iv), (v), (ix), (x), (xi), and (xii);
(i) a means for preparing a solution for determination, comprising preparing a solution for determination containing flavin, an electron donor, a spin trap agent, and an aqueous solvent,
(ii) a means for generating a spin adduct/radical for determination, comprising generating a superoxide spin adduct, an electron donor radical spin adduct, and/or an electron donor radical by irradiating the solution for determination with light,
(iii) a means for acquiring a spectrum for determination, comprising acquiring a spectrum by detecting the superoxide spin adduct, the electron donor radical spin adduct, and/or the electron donor radical thus generated by electron spin resonance,
(iv) a means for determining similarity, comprising determining whether or not a standard spectrum of a superoxide spin adduct and the spectrum for determination are similar,
(v) a means for acquiring a flavin concentration, comprising acquiring a flavin concentration of a solution for determination from which the spectrum for determination that is considered to be similar by the similarity determination is acquired,
(ix) a means for preparing a solution for evaluation, comprising preparing a solution for evaluation containing flavin at the concentration as acquired above, an electron donor, a spin trap agent, a sample to be evaluated for its superoxide scavenging ability, and an aqueous solvent,
(x) a means for generating a spin adduct for evaluation, comprising generating a spin adduct by irradiating the solution for evaluation with light,
(xi) a means for acquiring a spectrum for evaluation, comprising acquiring a spectrum by detecting the spin adduct for evaluation by electron spin resonance, and
(xii) a means for comparative evaluation, comprising evaluating a superoxide scavenging ability by comparing a standard spectrum of a superoxide spin adduct with the spectrum for evaluation.

20. The device according to claim 19, wherein the device comprises the following means (xiii) instead of the means (i), (ii), (iii), (iv), (v), and (ix), when flavin is riboflavin;
(xiii) a means for preparing a solution for evaluation, comprising preparing a solution for evaluation containing riboflavin, an electron donor, a spin trap agent, a sample to be evaluated for its superoxide scavenging ability, and an aqueous solvent so that a riboflavin concentration C (μmol/L) is 0.1<C≦15.

21. The device according to claim 19, wherein the means for acquiring a flavin concentration comprises acquiring a concentration of flavin that is found similar by the similarity determination so that a purity of the superoxide in a radical to be generated is 75.6 to 100%.

22. The device according to claim 19, wherein the electron donor is EDTA.

23. The device according to claim 19, wherein the spin trap agent is CYPMPO.

24. The device according to claim 19, wherein the aqueous solvent is a phosphate buffer.
